(19) United States
(12) Patent Application Publication
(10) Pub. No.: US 2025/0344589 A1
(43) Pub. Date: Nov. 6, 2025

(54) DISPLAY APPARATUS

(71) Applicant: SEMICONDUCTOR ENERGY LABORATORY CO., LTD., Atsugi-shi, Kanagawa-ken (JP)

(72) Inventors: Masahiro KATAYAMA, Isehara, Kanagawa (JP); Yukinori SHIMA, Tatebayashi, Gunma (JP); Masataka NAKADA, Tochigi, Tochigi (JP); Shingo EGUCHI, Atsugi, Kanagawa (JP); Daiki NAKAMURA, Atsugi, Kanagawa (JP); Koji KUSUNOKI, Isehara, Kanagawa (JP)

(21) Appl. No.: 18/580,265

(22) PCT Filed: Jul. 25, 2022
(86) PCT No.: PCT/IB2022/056827

§ 371 Date: Jan. 18, 2024

(30) Foreign Application Priority Data
Aug. 5, 2021 (JP) 2021-129045

(51) Int. Cl. H10K 59/131; H10K 59/80

(52) U.S. Cl. CPC H10K 59/1315; H10K 59/80515; H10K 59/80521

(57) ABSTRACT

A display apparatus in which a voltage drop is sufficiently suppressed is provided. The display apparatus includes a first light-emitting device including a first lower electrode and a first organic compound layer positioned over the first lower electrode; a second light-emitting device including a second lower electrode and a second organic compound layer positioned over the second lower electrode; a common electrode included in the first light-emitting device and the second light-emitting device; and an auxiliary wiring electrically connected to the common electrode. The auxiliary wiring includes a first wiring layer and a second wiring layer; the second wiring layer is electrically connected to the first wiring layer through a contact hole in an insulating layer; and the second wiring layer has a lattice shape in a top view.

### TECHNICAL FIELD

One embodiment of the present invention relates to a display apparatus.

Note that one embodiment of the present invention is not limited to the above technical field. Examples of the technical field of one embodiment of the present invention disclosed in this specification and the like include a semiconductor device, a light-emitting apparatus, a power storage device, a memory device, an electronic device, a lighting device, an input device, an input/output device, and a manufacturing method thereof.

### BACKGROUND ART

A structure of an active matrix display apparatus achieving high resolution has been proposed; the structure includes an upper auxiliary wiring placed adjacent to only a red pixel, and a lower auxiliary wiring connected to the upper auxiliary wiring to control an electric resistance of a cathode electrode (upper electrode) (see Patent Document 1).

As a method for manufacturing an organic EL element, a method for manufacturing an organic optoelectronic device employing standard UV photolithography is disclosed (see Non-Patent Document 1).

### REFERENCES

### Patent Document

[Patent Document 1] Japanese Published Patent Application No. 2010-85866

### Non-Patent Document

[Non-Patent Document 1]B. Lamprecht et al., “Organic optoelectronic device fabrication using standard UV photolithography”, phys. stat. sol. (RRL) 2, No. 1, pp. 16-18 (2008).

### SUMMARY OF THE INVENTION

### Problems to be Solved by the Invention

In the active matrix display apparatus disclosed in the above-described Patent Document 1, the lower auxiliary wiring is formed in the same layer as a power supply line and a scan line, and thus a voltage drop of the upper electrode cannot be sufficiently suppressed. A voltage drop occurs mainly due to a thin thickness of an electrode, a large area of an electrode, or the like, and refers to a state where voltage applied to the electrode is lowered by the amount of energy consumed by the heat generation of the electrode or the like.

Furthermore, it is difficult to provide a high-resolution display apparatus by the method disclosed in Non-Patent Document 1.

In view of the above, an object of one embodiment of the present invention is to provide a display apparatus in which a voltage drop is sufficiently suppressed and a method for manufacturing the display apparatus. Another object of one embodiment of the present invention is to provide a high-resolution display apparatus and a method for manufacturing the display apparatus.

Note that the description of these objects does not preclude the existence of other objects. These objects should be construed as being independent of one another. One embodiment of the present invention only needs to achieve at least one of these objects and does not necessarily achieve all the objects. Other objects can be derived from the description of the specification, the drawings, and the claims, which are this specification and the like.

### Means for Solving the Problems

In view of the above problems, one embodiment of the present invention is a display apparatus including a first light-emitting device including a first lower electrode and a first organic compound layer positioned over the first lower electrode; a second light-emitting device including a second lower electrode and a second organic compound layer positioned over the second lower electrode; a common electrode included in the first light-emitting device and the second light-emitting device; and an auxiliary wiring electrically connected to the common electrode. The auxiliary wiring includes a first wiring layer and a second wiring layer; the second wiring layer is electrically connected to the first wiring layer through a contact hole in an insulating layer; and the second wiring layer has a lattice shape in a top view.

Another embodiment of the present invention is a display apparatus including a first light-emitting device including a first lower electrode and a first organic compound layer positioned over the first lower electrode; a second light-emitting device including a second lower electrode and a second organic compound layer positioned over the second lower electrode; a common electrode included in the first light-emitting device and the second light-emitting device; and an auxiliary wiring electrically connected to the common electrode. The auxiliary wiring includes a first wiring layer and a second wiring layer; the second wiring layer is electrically connected to the first wiring layer through a contact hole in an insulating layer; the first wiring layer has a lattice shape in a top view; and the first lower electrode, the second lower electrode, and the second wiring layer each include a region positioned over the insulating layer.

Another embodiment of the present invention is a display apparatus including a first light-emitting device including a first lower electrode and a first organic compound layer positioned over the first lower electrode; a second light-emitting device including a second lower electrode and a second organic compound layer positioned over the second lower electrode; a common electrode included in the first light-emitting device and the second light-emitting device; and an auxiliary wiring electrically connected to the common electrode. The auxiliary wiring includes a first wiring layer and a second wiring layer; the second wiring layer is electrically connected to the first wiring layer through a contact hole in an insulating layer; the first wiring layer and the second wiring layer each have a lattice shape in a top view; the first lower electrode, the second lower electrode, and the second wiring layer each include a region positioned over the insulating layer; and a width of the second wiring layer is smaller than a width of the first wiring layer.

In the present invention, end portions of the first lower electrode and the second lower electrode each preferably have a tapered shape.

In the present invention, a taper angle of an end surface of the first organic compound layer is preferably greater than or equal to 450 and less than 90°.

In the present invention, a taper angle of an end surface of the second organic compound layer is preferably greater than or equal to 45° and less than 90°.

### Effect of the Invention

According to one embodiment of the present invention, it is possible to provide a display apparatus in which a voltage drop is sufficiently suppressed and a method for manufacturing the display apparatus. According to another embodiment of the present invention, a high-resolution display apparatus and a method for manufacturing the display apparatus can be provided.

Note that the description of these effects does not preclude the existence of other effects. These effects should be construed as being independent of one another. One embodiment of the present invention only needs to have at least one of these effects and does not necessarily have all the effects. Other effects can be derived from the description of the specification, the drawings, and the claims, which are the present specification and the like.

### BRIEF DESCRIPTION OF THE DRAWINGS

FIG. 1A is a conceptual diagram of a pixel portion including an auxiliary wiring, and FIG. 1B1 to FIG. 1C2 are each a top view of the pixel portion.

FIG. 2A is a conceptual diagram of a pixel portion including an auxiliary wiring, and FIG. 2B1 to FIG. 2C2 are each a top view of the pixel portion.

FIG. 3A is a conceptual diagram of a pixel portion including an auxiliary wiring, and FIG. 3B and FIG. 3C are each a top view of the pixel portion.

FIG. 4A is a cross-sectional view of a pixel portion, and FIG. 4B is a top view of the pixel portion.

FIG. 5A to FIG. 5D are each a top view of a pixel portion.

FIG. 6A and FIG. 6B are each a top view of a pixel portion.

FIG. 7A is a top view, FIG. 7B is a cross-sectional view of a pixel portion, and FIG. 7C is a cross-sectional view of a connection portion.

FIG. 8A to FIG. 8D are each a top view of a pixel portion.

FIG. 9A to FIG. 9D are each a top view of a pixel portion.

FIG. 10A is a conceptual diagram of a display apparatus, and FIG. 10B to FIG. 10E are pixel circuit diagrams.

FIG. 11A to FIG. 11D are each a cross-sectional view of a transistor.

FIG. 12A to FIG. 12C are each a top view of a pixel portion, and FIG. 12D is a circuit diagram.

FIG. 13A to FIG. 13C are cross-sectional views illustrating a manufacturing method.

FIG. 14A to FIG. 14C are cross-sectional views illustrating a manufacturing method.

FIG. 15A to FIG. 15C are cross-sectional views illustrating a manufacturing method.

FIG. 16A to FIG. 16C are cross-sectional views illustrating a manufacturing method.

FIG. 17A and FIG. 17B are cross-sectional views illustrating a manufacturing method.

FIG. 18A to FIG. 18C are cross-sectional views illustrating a manufacturing method.

FIG. 19A to FIG. 19C are cross-sectional views illustrating a manufacturing method.

FIG. 20A is a top view of a display apparatus, and FIG. 20B and FIG. 20C are perspective views of the display apparatus.

FIG. 21A and FIG. 21B are perspective views of a display apparatus.

FIG. 22A to FIG. 22D are diagrams of electronic devices.

FIG. 23A and FIG. 23B are diagrams of an electronic devices.

### MODE FOR CARRYING OUT THE INVENTION

In this specification and the like, components are classified based on their functions and the components are described using independent blocks in a diagram in some cases; however, it is difficult to classify actual components based on their functions, and one component may have a plurality of functions.

In this specification and the like, the terms “source” and “drain” of a transistor interchange with each other depending on the polarity of the transistor or the levels of potentials applied to the terminals. In general, in an n-channel transistor, a terminal to which a lower potential is supplied is called a source, and a terminal to which a higher potential is supplied is called a drain. In a p-channel transistor, a terminal to which a lower potential is supplied is called a drain, and a terminal to which a higher potential is supplied is called a source. In this specification and the like, for the sake of convenience, the connection relationship of a transistor is sometimes described assuming that the source and the drain are fixed; in reality, the names of the source and the drain interchange with each other according to the above relationship of the potentials.

In this specification and the like, a “source” of a transistor means a source region that is part of a semiconductor layer functioning as an active layer or means a source electrode connected to the source region. Similarly, a drain of a transistor means a drain region that is part of the semiconductor film or a drain electrode connected to the drain region. Moreover, a gate of a transistor means a gate electrode.

In this specification and the like, a state where transistors are connected in series means, for example, a state where only one of a source and a drain of a first transistor is connected to only one of a source and a drain of a second transistor. In addition, a state where transistors are connected in parallel means a state where one of a source and a drain of a first transistor is connected to one of a source and a drain of a second transistor and the other of the source and the drain of the first transistor is connected to the other of the source and the drain of the second transistor.

In this specification and the like, connection is sometimes referred to as electrical connection and may refer to a state where current, voltage, or a potential can be supplied or transmitted. Accordingly, connection may refer to connection via an element such as a wiring, a resistor, a diode, or a transistor. Electrical connection may refer to direct connection without via an element such as a wiring, a resistor, a diode, or a transistor.

In this specification and the like, a first electrode and a second electrode are used for description of a source and a drain of a transistor in some cases; when one of the first electrode and the second electrode refers to a source, the other thereof refers to a drain.

In this specification and the like, a conductive layer sometimes has a plurality of functions such as those of a wiring and an electrode.

In this specification and the like, a light-emitting device is referred to as a light-emitting element in some cases. A light-emitting device has a structure in which an organic compound layer is sandwiched between a pair of electrodes. One of the pair of electrodes is an anode, the other of the pair of electrodes is a cathode, and at least one organic compound layer is a light-emitting layer. The light-emitting layer contains a light-emitting material; a fluorescent material, a phosphorescent material, or the like can be used as the light-emitting material. The pair of electrodes may be referred to as a lower electrode and an upper electrode. One of the pair of electrodes can function as one of an anode and a cathode, and the other of the pair of electrodes can function as the other of the anode and the cathode.

In this specification and the like, a light-emitting device including an organic compound layer formed using a metal mask (MM) is sometimes referred to as a light-emitting device having an MM structure. In this specification and the like, a metal mask is sometimes referred to as a fine metal mask (FMM, a high-resolution metal mask) depending on the minuteness of its opening portions.

In this specification and the like, a light-emitting device including an organic compound layer formed without using a metal mask or a fine metal mask is sometimes referred to as a light-emitting device having a metal maskless (MML) structure.

In this specification and the like, light-emitting devices exhibiting, for example, red, green, and blue are sometimes referred to as a red light-emitting device, a green light-emitting device, and a blue light-emitting device, respectively.

In this specification and the like, a structure in which light-emitting layers of light-emitting devices of different colors are separately formed is sometimes referred to as an SBS (Side By Side) structure. For example, manufacturing a red light-emitting device, a green light-emitting device, and a blue light-emitting device having an SBS structure enables a full-color display apparatus.

In this specification and the like, a light-emitting device emitting white light is sometimes referred to as a white light-emitting device. Note that a combination of white light-emitting devices with coloring layers (e.g., color filters or color conversion layers) enables a full-color display apparatus.

Light-emitting devices can be classified roughly into a single structure and a tandem structure. A single structure is a structure including one light-emitting unit between a pair of electrodes. The light-emitting unit refers to a stack including one or more light-emitting layers.

In order to obtain a white light-emitting device having a single structure, two or more light-emitting layers may be included in a light-emitting unit. Two or more light-emitting layers may be in contact with each other in the light-emitting unit. A white light-emitting device can be obtained even when three or more light-emitting layers are used. The three or more light-emitting layers may be in contact with each other in the light-emitting unit.

A tandem structure includes two or more light-emitting units between a pair of electrodes. In the tandem structure, an intermediate layer such as a charge-generation layer is suitably provided between the two or more light-emitting units. Note that the charge-generation layer has a function of injecting holes into one of the light-emitting units that is formed in contact with the charge-generation layer and a function of injecting electrons into the other light-emitting unit, when voltage is applied between the cathode and the anode. For example, in the tandem structure in which a first light-emitting unit, a charge-generation layer, and a second light-emitting unit are stacked between a pair of electrodes, through the charge-generation layer, holes are injected into the first light-emitting unit and electrons are injected into the second light-emitting unit.

To obtain a white light-emitting device having a tandem structure, the light-emitting device is configured to obtain white light emission by combining light from light-emitting layers of two or more light-emitting units.

When the white-light-emitting device and a light-emitting device having an SBS structure are compared to each other, the light-emitting device having an SBS structure can have lower power consumption than the white-light-emitting device. To reduce power consumption, a light-emitting device having an SBS structure is preferably used. Meanwhile, the white-light-emitting device is suitable in terms of lower manufacturing cost or higher manufacturing yield because the manufacturing process of the white-light-emitting device is simpler than that of the light-emitting device having an SBS structure.

In this specification and the like, a structure in which a connector such as an FPC (Flexible Printed Circuit) or a TCP (Tape Carrier Package) is attached to a substrate of a display panel, or a structure in which an IC is mounted on a substrate by a COG (Chip On Glass) method or the like is referred to as a display module in some cases. Thus, the display module is one embodiment of a display apparatus.

Next, embodiments are described in detail with reference to the drawings. Note that the present invention is not limited to the following description, and it will be readily understood by those skilled in the art that modes and details of the present invention can be modified in various ways without departing from the spirit and scope of the present invention. Thus, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

In this embodiment, a structure example of a display apparatus of one embodiment of the present invention will be described.

### <Function of Auxiliary Wiring>

The display apparatus described in this embodiment has a feature of including an auxiliary wiring. The auxiliary wiring is a layer having a function of an auxiliary to a main electrode, and the function of an auxiliary described in this embodiment includes a function of inhibiting a voltage drop due to a main electrode, for example. As the main electrode, a pair of electrodes of the light-emitting device can be given, for example; however, the pair of electrodes has a function of a cathode or an anode of the light-emitting device, and accordingly, a conductive material selected on the basis of the work function needs to be selected in some cases. The resistivity of the conductive material may be high when selected in consideration of only its work function. Thus, the display apparatus described in this embodiment has a feature that the auxiliary wiring is electrically connected to one of the pair of electrodes, whereby an effect of inhibiting the voltage drop can be obtained.

An upper electrode is given as a pair of electrodes; the upper electrode can be formed from a continuous conductive layer without being divided between a plurality of light-emitting devices. The continuous electrode is referred to as a common electrode in some cases. The common electrode needs to be formed in a larger area as the size of the display apparatus increases; such a common electrode makes a voltage drop easily occur. Thus, the display apparatus described in this embodiment is typically a display apparatus having an increased size and a feature of electrically connecting the auxiliary wiring to the upper electrode, whereby an effect of inhibiting the voltage drop can be obtained.

Note that the auxiliary wiring is sometimes referred to as an auxiliary electrode depending on the shape. There is no limitation on the shape of the auxiliary wiring in this specification and the like, and the auxiliary wiring includes an auxiliary electrode.

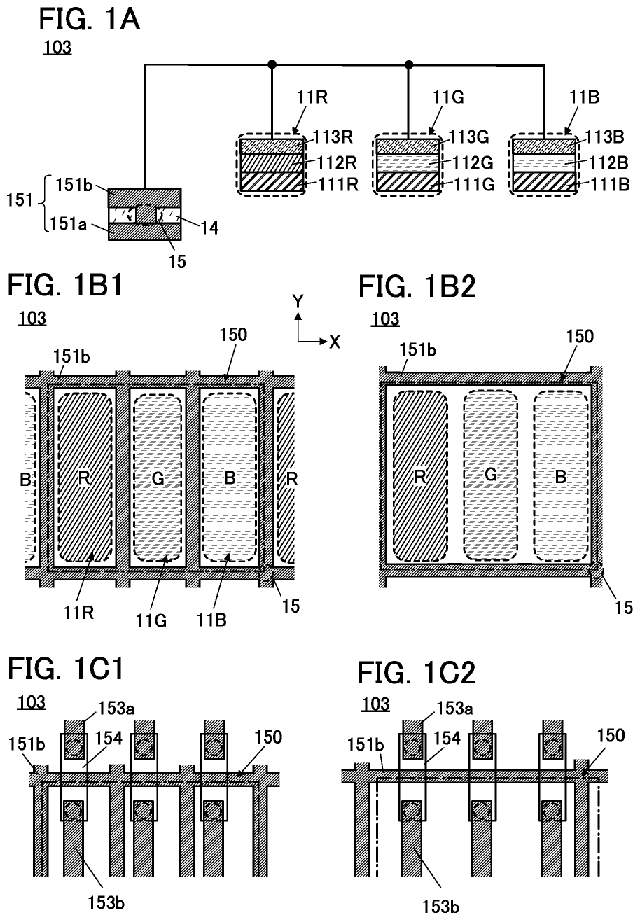

FIG. 1A is a conceptual diagram of a pixel portion 103 included in a display apparatus of one embodiment of the present invention. The pixel portion 103 includes at least a light-emitting device and also includes an auxiliary wiring 151 of one embodiment of the present invention. FIG. 1A illustrates light-emitting devices 11R, 11G, and 11B as examples of three light-emitting devices included in the pixel portion 103. The light-emitting device 11 is sometimes referred to when the light-emitting devices 11R, 11G, and 11B are not distinguished from each other.

### <Light Emitting Device>

The light-emitting device 11 has a structure in which at least a lower electrode, an organic compound layer, and an upper electrode are stacked in this order. FIG. 1A illustrates lower electrodes 111R, 111G, and 111B, organic compound layers 112R, 112G, and 112B, and upper electrodes 113R, 113G, and 113B. Note that when the lower electrodes 111R, 111G, and 111B are not distinguished from each other, they may each be referred to as the lower electrode 111. Note that when the organic compound layers 112R, 112G, and 112B are not distinguished from each other, they may each be referred to as the organic compound layer 112. Note that when the upper electrode 113R, 113G, and 113B are not distinguished from each other, they may each be referred to as the upper electrode 113E. The three light-emitting devices included in the pixel portion 103 can exhibit red (R), green (G), and blue (B), and the above-described reference numerals with RGB correspond to the respective colors. The organic compound layers 112R, 112G, and 112B include at least light-emitting layers, and the light-emitting layers are formed from different light-emitting materials or the like, whereby red (R), green (G), and blue (B) can be exhibited. Note that although the organic compound layer 112 includes components other than the light-emitting layer, the components other than the light-emitting layer will be described later.

### <Method for Forming Organic Compound Layer>

The organic compound layer 112 is a stack of a light-emitting layer and other layers, and each layer can be formed by an evaporation method using a metal mask. As described above, a light-emitting device including an organic compound layer formed using a metal mask is referred to as a light-emitting device having an MM structure. Each layer of the organic compound layer 112 can also be formed through a photolithography process without using a metal mask. As described above, a light-emitting device including an organic compound layer formed without using a metal mask is referred to as a light-emitting device having an MML structure. Note that a formation method including a photolithography process will be described later.

### <Upper Electrode and Common Electrode>

The upper electrode 113E included in the light-emitting devices may be divided for each light-emitting device. FIG. 1A illustrates a divided upper electrode and the auxiliary wiring 151 electrically connected to the upper electrode 113E. The electrical connection is shown by a solid line in FIG. 1A in the same manner as in a circuit diagram. A display apparatus including an upper electrode to which the auxiliary wiring 151 is electrically connected is preferable in terms of inhibition of a voltage drop.

The upper electrode may be provided as a common electrode, which is a continuous electrode, without being divided for each light-emitting device. In the case of using a common wiring, a voltage drop is likely to occur; accordingly, a structure in which the auxiliary wiring of one embodiment of the present invention is provided is suitably employed. Note that it is possible for those skilled in the art reading this specification and the like to understand the effect of the auxiliary wiring 151 by interchanging an upper electrode and a common electrode as appropriate.

Furthermore, since the voltage drop due to the upper electrode or the like is likely to occur as the size of the display apparatus increases, it is also possible for those skilled in the art reading this specification and the like to understand that the auxiliary wiring 151 has a significant effect in a large display apparatus.

### <Structure of Auxiliary Wiring>

The auxiliary wiring 151 preferably includes two or more wiring layers provided in different layers. For example, the auxiliary wiring 151 includes a first wiring layer 151a and a second wiring layer 151b as illustrated in FIG. 1A. The first wiring layer 151a is formed in a layer different from that of the second wiring layer 151b, and the formation surface of the first wiring layer 151a is different from that of the second wiring layer 151b.

Note that the wiring layer is sometimes referred to as an electrode layer depending on the shape. There is no limitation on the shape of the electrode layer in this specification and the like, and the wiring layer includes an electrode layer.

The first wiring layer 151a and the second wiring layer 151b are electrically connected to each other, so that the first wiring layer 151a and the second wiring layer 151b can function as the auxiliary wiring 151. Specifically, the first wiring layer 151a is electrically connected to the second wiring layer 151b through a contact hole 15 of an insulating layer 14 positioned between the first wiring layer 151a and the second wiring layer 151b.

There is no limitation on the number of stacked wiring layers included in the auxiliary wiring, and the auxiliary wiring may include three or more wiring layers such as a first wiring layer to a third wiring layer. It can be said that a larger number of wiring layers is preferable because it can increase the degree of freedom of arrangement (hereinafter, sometimes referred to as layout) of the wiring layers functioning as the auxiliary wiring accordingly.

In this manner, the auxiliary wiring 151 of one embodiment of the present invention has a feature that two or more wiring layers are provided in different layers, and the wiring layers positioned in different layers are electrically connected to each other through a contact hole.

### <Contact Hole>

A contact hole refers to an opening formed in an insulating layer and enables a wiring layer positioned below the insulating layer (referred to as a lower wiring layer) to be electrically connected to a wiring layer positioned above the insulating layer (referred to as an upper wiring layer). For the electrical connection, specifically, it is preferable that the lower wiring layer include a region exposed to an opening and that the upper wiring layer be electrically connected to or typically in contact with the exposed region.

In addition, insulating layers provided with contact holes may be stacked. This layer is referred to as an insulating layer having a stacked-layer structure and is rephrased as a stacked insulating layer. For example, a contact hole can be formed in the stacked insulating layer formed of a first insulating layer and a second insulating layer. In this case, a first contact hole is formed in the first insulating layer, and a second contact hole is formed in the second insulating layer. When the first contact hole includes at least a region overlapping with the second contact hole, the lower wiring layer and the upper wiring layer can be electrically connected to each other. For example, in the case where the second insulating layer is positioned over the first insulating layer, the width of the second contact hole is preferably larger than the width of the first contact hole in a cross-sectional view. Needless to say, as long as the lower wiring layer can be electrically connected to the upper wiring layer, there is no limitation on the width of the contact hole in each insulating layer.

The interval between the lower electrodes 111 is narrowed in a high-resolution display apparatus; accordingly, it is difficult to lay out the auxiliary wiring 151 on the basis of the interval. Thus, the layout of the auxiliary wiring 151 which is not affected or hardly affected by the interval between the lower electrodes 111 is desired.

As a layout of the auxiliary wiring 151 that is not affected by the lower electrodes 111, typically, both the first wiring layer 151a and the second wiring layer 151b are formed in a layer different from that of the lower electrodes 111. For example, the auxiliary wiring 151 in which the first wiring layer 151a and the second wiring layer 151b are positioned below the lower electrodes 111 is formed.

Furthermore, the shape or, typically, the area of the first wiring layer 151a in a top view can be different from that of the second wiring layer 151b. For example, the first wiring layer 151a is formed to have a smaller area than the second wiring layer 151b. In other words, the second wiring layer 151b may be laid out so as to have a larger area than the first wiring layer 151a. For example, the second wiring layer 151b can be laid out in a lattice shape. At this time, the second wiring layer 151b may have a band shape or an island shape. A lattice shape means one of patterns obtained by combining a plurality of vertical parallel lines and a plurality of horizontal parallel lines. The band shape is referred to as a rectangular shape or a stripe shape in some cases. The island shape refers to a shape having a shorter length than the band shape. Needless to say, the first wiring layer 151a may have a lattice shape, in which case the second wiring layer 151b may have a band shape.

FIG. 1B1 and FIG. 1B2 each illustrate a top view of the pixel portion 103 and illustrate a lattice-shaped second wiring layer 151b. Although not illustrated, the first wiring layer 151a is electrically connected to the second wiring layer 151b through the contact hole 15. Note that the first wiring layer 151a may be any shape and can have a band shape or an island shape, for example. The first wiring layer 151a preferably includes a region overlapping with part of the second wiring layer 151b, in which case electrical connection is easily obtained through the contact hole 15.

In FIG. 1B1 and FIG. 1B2, the X direction and the Y direction intersecting with the X direction are added, and a structure of the pixel portion 103 or the like is described with the use of the directions in some cases.

The lattice-shaped second wiring layer 151b illustrated in FIG. 1B1 includes a plurality of vertical lines along the Y direction. The vertical lines overlap with gaps between the subpixels. The gaps between the subpixels include a region between the end of the lower electrode 111R and the end of the lower electrode 111G and a region between the end of the lower electrode 111G and the end of the lower electrode 111B.

In FIG. 1B2, the second wiring layer 151b is different from that in FIG. 1B1 in the interval of the vertical lines, and the vertical lines overlap with a gap between the pixels 150. The gap between the pixels 150 includes, for example, a region between the end of the lower electrode 111B corresponding to the subpixel B positioned at the end of the pixel 150 and the end of the lower electrode 111R corresponding to the subpixel R positioned at the end of the adjacent pixel. “Adjacent” means any of a relation of being adjacent to each other along the X direction and a relation of being adjacent to each other along the Y direction. In other words, the second wiring layer 151b illustrated in FIG. 1B2 does not include a vertical line including a region overlapping with a gap between the subpixels as illustrated in FIG. 1B1.

In a display apparatus with an increased aperture ratio or a display apparatus with increased resolution, a gap between the lower electrodes is narrowed, and accordingly, an auxiliary wiring is difficult to be laid out in the gap between the lower electrodes. The gap between the lower electrodes is, for example, the distance between the end of the lower electrode 111R and the end of the lower electrode 111G or the distance between the end of the lower electrode 111G and the end of the lower electrode 111B. Thus, in the case where the second wiring layer 151b is positioned in the same layer as the lower electrodes 111 and the display apparatus has increased resolution, the second wiring layer 151b preferably employs a layout with less vertical lines as illustrated in FIG. 1B2.

A layer positioned in the same layer as the lattice-shaped second wiring layer 151b preferably has no wiring functioning as a scan line, a signal line, a power supply line, and the like. This is because the wiring having the above functions needs to extend in the X direction or the Y direction and thus is in contact with the second wiring layer 151b. In the case of providing a scan line, a signal line, and a power supply line, they are laid out in island shapes by adjusting the length thereof along the X direction or that along the Y direction so as not to be in contact with the second wiring layer. Then, electrical connection between island-shaped scan lines and the like is obtained using a conductive layer in a layer different from that of the second wiring layer. A wiring for obtaining such electrical connection is sometimes referred to as a bridge wiring.

Note that the bridge wiring is sometimes referred to as a bridge electrode depending on the shape. There is no limitation on the shape of the bridge wiring in this specification and the like, and the bridge wiring includes a bridge electrode.

FIG. 1C1 and FIG. 1C2 illustrate the pixel portion 103 including a signal line and a bridge wiring. Although the light-emitting devices 11R, 11G, and 11B are not illustrated in FIG. 1C1 and FIG. 1C2, the layouts or the like of the light-emitting devices 11R, 11G, and 11B in FIG. 1B1 and FIG. 1B2 can be referred to for those in FIG. 1C1 and FIG. 1C2.

The signal line illustrated in FIG. 1C1 and FIG. 1C2 includes a third wiring layer 153a and a fourth wiring layer 153b, and the third wiring layer 153a and the fourth wiring layer 153b are separated from each other. The third wiring layer 153a and the fourth wiring layer 153b may be referred to as island-shaped wiring layers. The island-shaped wiring layers are electrically connected to each other using a bridge wiring 154. Both the third wiring layer 153a and the fourth wiring layer 153b are preferably formed using a conductive layer positioned on a formation surface different from that of the second wiring layer 151b. For example, both the third wiring layer 153a and the fourth wiring layer 153b are preferably formed using a conductive layer positioned below the second wiring layer 151b. Furthermore, the third wiring layer 153a and the fourth wiring layer 153b may be formed using a conductive layer positioned on the same formation surface as the second wiring layer 151b. In any case, the bridge wiring 154 is formed using a conductive layer positioned on a formation surface different from that of the second wiring layer 151b. For example, a conductive layer positioned below the second wiring layer 151b is used as the bridge wiring 154.

Also in the case where a scan line or a power supply line is formed using an island-shaped wiring layer in addition to the signal line, electrical connection can be obtained by the bridge wiring 154 or the like.

The layout of the second wiring layer 151b with less vertical lines as illustrated in FIG. 1B2 is also suitably used when the signal line and the bridge wiring are included as illustrated in FIG. 1C2.

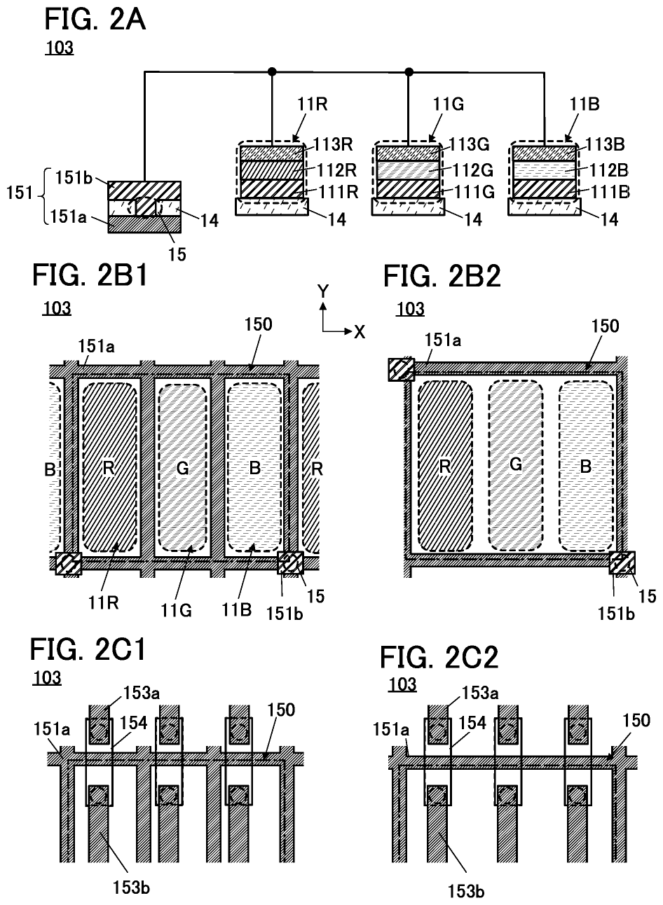

Next, FIG. 2A illustrates another form of the pixel portion 103. FIG. 2A illustrates a structure in which the second wiring layer 151b is positioned on the same formation surface as the lower electrodes 111. Note that “the same formation surface” corresponds to the top surface of the insulating layer 14. The other structures are similar to those in FIG. 1A.

FIG. 2B1 and FIG. 2B2 each illustrate a top view of the pixel portion 103 and illustrate a lattice-shaped first wiring layer 151a. For the lattice layout, the layout of the lattice-shaped second wiring layer 151b illustrated in FIG. 1B1 and FIG. 1B2 can be referred to.

In the contact hole 15 illustrated in FIG. 2B1 and FIG. 2B2, the second wiring layer 151b is positioned so as to overlap with an intersection of the lattice-shaped first wiring layer 151a. The second wiring layer 151b overlaps with the above-described intersection and does not need to overlap with the whole lattice-shaped first wiring layer 151a. Furthermore, the second wiring layer 151b does not need to overlap with all intersections. Since the second wiring layer 151b includes the same conductive layer as the lower electrodes 111, the second wiring layer 151b needs to be laid out so as not to be in contact with the lower electrodes 111; however, the layout of the first wiring layer 151a is not affected by the lower electrodes 111. Thus, the first wiring layer 151a can have a large area, and a voltage drop can be inhibited even when the second wiring layer 151b has a small area. The second wiring layer 151b laid out in a small area is preferably referred to as an electrode layer in some cases.

FIG. 2C1 and FIG. 2C2 each illustrate the pixel portion 103 including a signal line and a bridge wiring. Although the light-emitting devices 11R, 11G, and 11B are not illustrated in FIG. 2C1 and FIG. 2C2, the layouts or the like of the light-emitting devices 11R, 11G, and 11B in FIG. 2B1 and FIG. 2B2 can be referred to for those in FIG. 2C1 and FIG. 2C2.

The signal line illustrated in FIG. 2C1 and FIG. 2C2 includes the third wiring layer 153a and the fourth wiring layer 153b, and the third wiring layer 153a and the fourth wiring layer 153b are separated from each other. As described above, the third wiring layer 153a and the fourth wiring layer 153b may be referred to as island-shaped wiring layers, and the island-shaped wiring layers are electrically connected to each other using the bridge wiring 154. Both the third wiring layer 153a and the fourth wiring layer 153b are preferably formed using a conductive layer positioned on a formation surface different from that of the second wiring layer 151b. For example, both the third wiring layer 153a and the fourth wiring layer 153b are preferably formed using a conductive layer positioned below the second wiring layer 151b. Furthermore, the third wiring layer 153a and the fourth wiring layer 153b are preferably formed using a conductive layer positioned on the same formation surface as that of the first wiring layer 151a. In any case, the bridge wiring 154 is formed using a conductive layer positioned on a formation surface different from that of the first wiring layer 151a. For example, a conductive layer positioned below the first wiring layer 151a is used as the bridge wiring 154. The bridge wiring 154 may be formed using a conductive layer positioned on the same formation surface as the second wiring layer 151b. In this case, the lower electrodes 111 and the bridge wiring 154 are laid out so as not to be in contact with each other.

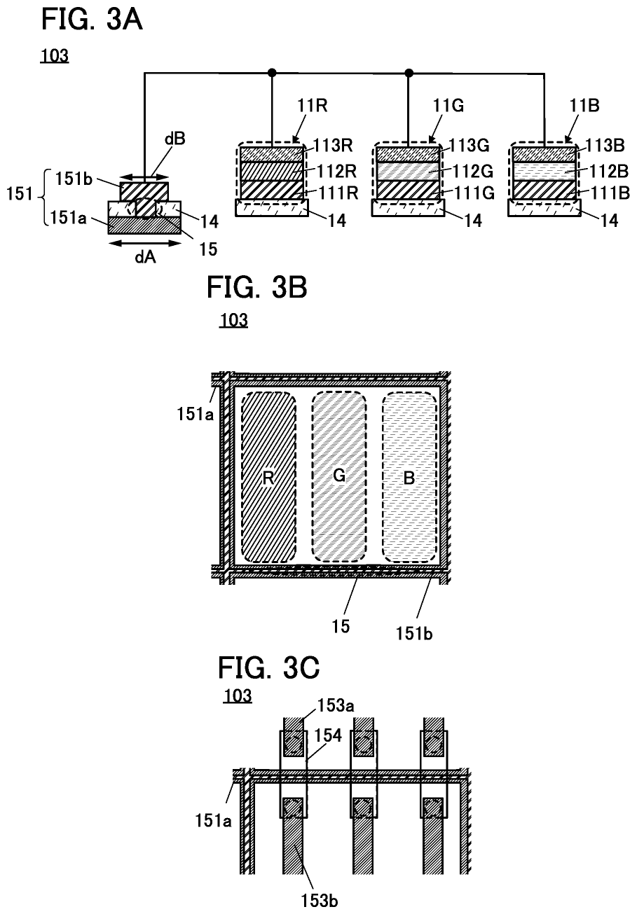

Next, FIG. 3A illustrates another form of the pixel portion 103 of one embodiment of the present invention. FIG. 3A has a structure different from that in FIG. 2A in that the width of the second wiring layer 151b (the width denoted by dB) is smaller than the width of the first wiring layer 151a (the width denoted by dA) in a cross-sectional view. The other structures can be similar to those in FIG. 2A.

FIG. 3B illustrates a top view of the pixel portion 103 and illustrates a state where the first wiring layer 151a and the second wiring layer 151b each have a lattice shape. For the lattice layout, the layout of the lattice-shaped second wiring layer 151b illustrated in FIG. 1B2 is referred to.

The contact hole 15 illustrated in FIG. 3B can have a shape fit with a region where the first wiring layer 151a and the second wiring layer 151b overlap with each other. For example, the contact hole 15 can have a shape along one side of the second wiring layer 151b.

FIG. 3C illustrates the pixel portion 103 including a signal line and abridge wiring. The signal line illustrated in FIG. 3C includes the third wiring layer 153a and the fourth wiring layer 153b, and the third wiring layer 153a and the fourth wiring layer 153b are separated from each other. Thus, the third wiring layer 153a and the fourth wiring layer 153b are electrically connected to each other using the bridge wiring 154. The third wiring layer 153a and the fourth wiring layer 153b each include a conductive layer in the same layer as the first wiring layer 151a. The bridge wiring 154 includes a conductive layer in a layer different from that provided with the first wiring layer 151a and preferably includes a conductive layer in a layer below the first wiring layer 151a.

In this manner, the auxiliary wiring 151 of one embodiment of the present invention includes two or more wiring layers provided in different layers, which is preferable because of offering a higher layout flexibility of the auxiliary wiring 151 than the case where an auxiliary wiring is formed from one wiring layer. The auxiliary wiring 151 of one embodiment of the present invention is suitably used in a high-resolution display apparatus.

### <Conductive Material Included in Auxiliary Wiring>

For the conductive material included in the auxiliary wiring 151 of one embodiment of the present invention, i.e., the conductive material included in the first wiring layer 151a or the second wiring layer 151b, a metal such as aluminum, copper, silver, gold, platinum, chromium, molybdenum, or the like can be used. For the conductive material, an alloy of the above-described metal can be used. The above-described conductive material is a metal and is a non-light-transmitting conductive material. The first wiring layer 151a or the second wiring layer 151b can be formed of a single layer or a stacked layer using the above conductive materials. For example, it may be possible that the first wiring layer 151a is a stacked layer and the second wiring layer 151b is a single layer. Alternatively, it may be possible that the first wiring layer 151a is a single layer and the second wiring layer 151b is a stacked layer. Alternatively, it may be possible that the first wiring layer 151a is a stacked layer and the second wiring layer 151b is also a stacked layer.

As the conductive material included in the auxiliary wiring of one embodiment of the present invention, i.e., the conductive material included in the first wiring layer 151a or the second wiring layer 151b, a light-transmitting conductive material may be used. Specifically, it is possible to use an oxide containing indium and tin (also referred to as an indium tin oxide, an In—Sn oxide, or an ITO), an oxide containing indium, silicon, and tin (also referred to as an In—Si—Sn oxide or ITSO), an oxide containing indium and zinc (also referred to as an indium zinc oxide or an In—Zn oxide), an oxide containing indium, tungsten, and zinc (also referred to as an In—W—Zn oxide), or the like. The first wiring layer 151a or the second wiring layer 151b can be formed to be a single layer or a stacked layer using the above conductive materials. In the case where the first wiring layer 151a or the second wiring layer 151b has a stacked-layer structure, a conductive material including the above metals or the like is preferably included in at least one or more of the layers.

The resistivity of the conductive material used for the auxiliary wiring of one embodiment of the present invention, that is, the resistivity of the conductive material used for the first wiring layer 151a or the second wiring layer 151b, is preferably lower than the resistivity of the conductive material used for the common electrode. However, in the case where a voltage drop due to the common electrode can be sufficiently inhibited, it may be possible that the above resistivity relation is not satisfied.

This embodiment can be combined with the other embodiments as appropriate. In this specification, in the case where a plurality of structure examples are described in one embodiment, the structure examples can be combined as appropriate.

### Embodiment 2

In this embodiment, a specific example of a display apparatus of one embodiment of the present invention will be described.

### <Top-Emission Structure>

The display apparatus of one embodiment of the present invention preferably employs a top-emission structure. In the top-emission structure, the upper electrode needs to have a light-transmitting property, and light is emitted in the direction of the upper electrode. The light-transmitting property means to transmit visible light (light with a wavelength greater than or equal to 400 nm and less than 750 nm), preferably with a transmittance higher than or equal to 40%.

A light-transmitting conductive material sometimes has high resistivity, in which case a common electrode has high resistance. This causes a voltage drop due to the common electrode and an uneven potential distribution in the display surface, leading to a variation in the luminance of the light-emitting device. In view of the above, the display apparatus having a top-emission structure of one embodiment of the present invention may include an auxiliary wiring electrically connected to the common electrode. The auxiliary wiring can have an effect of inhibiting a voltage drop. The upper electrode may be rephrased as the common electrode.

### <Bottom-Emission Structure>

Note that the display apparatus of one embodiment of the present invention may have a bottom-emission structure and may include an auxiliary wiring electrically connected to the common electrode. The auxiliary wiring can have an effect of inhibiting a voltage drop.

Note that in the bottom-emission structure, the lower electrode needs to have a light-transmitting property, and light is emitted in the direction of the lower electrode.

### <Dual-Emission Structure>

Note that the display apparatus of one embodiment of the present invention may have a dual-emission structure and may include an auxiliary wiring electrically connected to the common electrode. The auxiliary wiring can have an effect of inhibiting a voltage drop.

In the dual-emission structure, the lower electrode and the upper electrode need to have a light-transmitting property, and light is emitted in both directions of the lower electrode and the upper electrode. The dual-emission display apparatus can be referred to as a transparent display.

In this embodiment, a structure in which an auxiliary wiring is used in a display apparatus having a top-emission structure will be described.

### [Specific Example of Auxiliary Wiring]

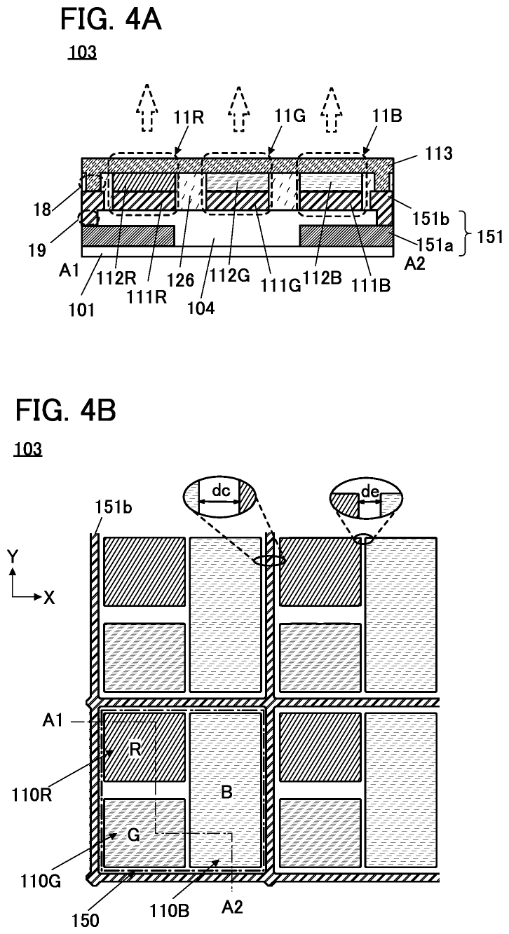

FIG. 4A illustrates a pixel portion 103 included in a display apparatus having a top-emission structure, and illustrates a cross-sectional view of the auxiliary wiring 151 or the like. Although the cross-sectional structure of the auxiliary wiring 151 described in FIG. 3 and the like in the above embodiment is used in FIG. 4A, the display apparatus having a top-emission structure may have a cross-sectional structure of the auxiliary wiring 151 described in FIG. 1, FIG. 2, and the like in the above embodiment.

The pixel portion 103 includes the light-emitting device 11, and the light-emitting device 11 includes the common electrode 113. Since the common electrode 113 has a light-transmitting property, light is emitted from each light-emitting device to the arrow direction indicated in FIG. 4A. The light-emitting device 11 is formed over an insulating layer 104, and the insulating layer 104 is formed over the substrate 101.

As illustrated in FIG. 4(A), the auxiliary wiring 151 includes the first wiring layer 151a and the second wiring layer 151b. The first wiring layer 151a is a wiring layer formed over the substrate 101, and the second wiring layer 151b is a wiring layer formed over the insulating layer 104. The second wiring layer 151b is electrically connected to the first wiring layer 151a through a contact hole 19 in the insulating layer 104 and functions as the auxiliary wiring 151. The common electrode 113 is positioned over the insulating layer 126, and the common electrode 113 can be electrically connected to the auxiliary wiring 151 through a contact hole 18 in the insulating layer 126.

The auxiliary wiring 151 including two or more wiring layers provided in different layers is preferable because it can be formed without being affected by the layout of the lower electrode or with the minimized influence of the layout of the lower electrode even when any one of the wiring layers is provided on the same formation surface as that of the lower electrodes 111.

Although the second wiring layer 151b is provided in the same layer as the lower electrodes 111 in FIG. 4A, the first wiring layer 151a is provided in a layer different from that provided with the lower electrodes 111; thus, the first wiring layer 151a can be laid out in a larger area than the second wiring layer 151b. In the case where the first wiring layer 151a is positioned below the lower electrodes 111, the layout flexibility is increased without a decrease in an aperture ratio. The first wiring layer 151a formed at a position that does not decrease the aperture ratio does not need to have a light-transmitting property and accordingly, a conductive material with low resistivity can be used.

In this manner, the auxiliary wiring 151 of one embodiment of the present invention can include a wiring layer on the formation surface different from that of the lower electrodes, and the wiring layer can be formed to have a large area without being affected by the layout of the lower electrodes, whereby the effect of inhibiting a voltage drop can be sufficiently exhibited.

Next, a structure other than the auxiliary wiring 151 in the pixel portion 103 is described. A top view of the pixel portion 103 illustrated in FIG. 4B is also referred to. Note that in FIG. 4B, the second wiring layer 151b is illustrated, and the first wiring layer 151a is omitted.

In FIG. 4B, A1-A2 denoted by dashed-dotted line corresponds to A1-A2 in FIG. 4A. In FIG. 4B, the X direction and the Y direction intersecting with the X direction are added, and a layout or the like of a structure included in the pixel portion 103 is described with the use of the directions in some cases.

As illustrated in FIG. 4B, the pixel portion 103 positioned in the display region includes a plurality of pixels 150. The pixel 150 is used as a minimum unit capable of full-color display and includes at least a subpixel 110R, a subpixel 110G, and a subpixel 110B as illustrated in FIG. 4B. Note that to perform full-color display, the subpixel 110R, the subpixel 110G, and the subpixel 110B may each include a coloring layer; a color filter or a color conversion layer is given as an example of the coloring layer.

Matters common to the subpixel 110R, the subpixel 110G, and the subpixel 110B are sometimes described using the collective term “subpixel 110”.

The subpixel 110R, the subpixel 110G, and the subpixel 110B correspond to light-emitting regions of light-emitting devices, and FIG. 4B illustrates each light-emitting region as a rectangular shape. The subpixel 110R in FIG. 4B corresponds to a light-emitting region of a red light-emitting device (illustrated as R), the subpixel 110G corresponds to a light-emitting region of a green light-emitting device (illustrated as G), and the subpixel 110B corresponds to a light-emitting region of a blue light-emitting device (illustrated as B). Note that the display apparatus of one embodiment of the present invention is not limited to the above emission color, and may include a white light-emitting device in addition to red, green, and blue light-emitting devices, for example.

As illustrated in FIG. 4B, a plurality of subpixels 110R and a plurality of subpixels 110G are alternately arranged along the Y direction. A plurality of subpixels 110B are arranged along the Y direction. The subpixel 110B can have a larger area than the subpixel 110R and the subpixel 110G. For example, in the case where a light-emitting layer containing a fluorescent material is used for the blue light-emitting device and a light-emitting layer containing a phosphorescent material is used for each of the red light-emitting device and the green light-emitting device, the subpixel 110B preferably has a larger area than the subpixel 110R and the subpixel 110G as illustrated in FIG. 4B.

As described above, as illustrated in FIG. 4A, in the subpixel 110R, the insulating layer 104 is provided over the substrate 101, the lower electrode 111R of the light-emitting device 11R is provided over the insulating layer 104, the organic compound layer 112R of the light-emitting device 11R is provided over the lower electrode 111R, and the common electrode 113 is provided over the organic compound layer 112R. The light-emitting device 11R emits light to the common electrode 113 side, i.e., in the direction indicated by the arrow in FIG. 4A.

As described above, as illustrated in FIG. 4A, in the subpixel 110G, the insulating layer 104 is provided over the substrate 101, the lower electrode 111G of the light-emitting device 11G is provided over the insulating layer 104, the organic compound layer 112G of the light-emitting device 11G is provided over the lower electrode 111G, and the common electrode 113 is provided over the organic compound layer 112G. The light-emitting device 11G emits light to the common electrode 113 side, i.e., in the direction indicated by the arrow in FIG. 4A.

As described above, as illustrated in FIG. 4A, in the subpixel 110B, the insulating layer 104 is provided over the substrate 101, the lower electrode 111B of the light-emitting device 11B is provided over the insulating layer 104, the organic compound layer 112B of the light-emitting device 11B is provided over the lower electrode 111B, and the common electrode 113 is provided over the organic compound layer 112B. The light-emitting device 11B emits light to the common electrode 113 side, i.e., in the direction indicated by the arrow in FIG. 4A.

The subpixel 110 includes a switching element controlling the light-emitting device in addition to the above light-emitting device; however, the switching element is not illustrated in FIG. 4A and FIG. 4B. In the display apparatus of one embodiment of the present invention, light is emitted from the light-emitting device controlled by the switching element, which enables full-color display.

As illustrated in FIG. 4A, the second wiring layer 151b is formed using a conductive layer provided in the same layer as the lower electrodes 111. In addition, the first wiring layer 151a is a wiring layer provided in the layer different from that of the lower electrodes 111.

As illustrated in FIG. 4A, the second wiring layer 151b includes a wiring layer on the same formation surface as the lower electrodes and is accordingly provided in a region not in contact with the lower electrodes 111, i.e., not overlapping with the subpixels. For example, the second wiring layer 151b has a lattice shape in a top view. The lattice-shaped second wiring layer 151b includes regions extending along the X direction and arranged in parallel as horizontal lines and includes regions extending along the Y direction and arranged in parallel as vertical lines.

The second wiring layer 151b illustrated in FIG. 4B includes regions positioned between the subpixels 110R and the subpixels 110G as the regions extending along the X direction, and the regions are arranged in parallel. The regions positioned between the subpixels 110R and the subpixels 110G correspond to regions between pixels. The second wiring layer 151b illustrated in FIG. 4B includes regions positioned between the subpixels 110G and the subpixels 110B as the regions extending along the Y direction, and the regions are arranged in parallel.

A gap between the lower electrodes 111 is narrower in the display apparatus with higher resolution. For example, in the pixel portion 103 in FIG. 4B included in a high-resolution display apparatus, de between the subpixels and dc between the pixels are narrow. It becomes more difficult to form a wiring layer for an auxiliary wiring as the interval becomes more narrowed. Thus, it is preferable that a wiring layer overlapping with the gap between the subpixels in the top view be the first wiring layer 151a and the first wiring layer 151a be a wiring layer in the layer different from that provided with the lower electrode.

### <Insulating Layer 126>

In the display apparatus of one embodiment of the present invention, the insulating layer 126 is preferably positioned between the light-emitting devices as illustrated in FIG. 4A. The insulating layer 126 can fill spaces between the pixels and between the subpixels, and the second wiring layer 151b is preferably provided to overlap with the insulating layer 126. The insulating layer 126 can inhibit the second wiring layer 151b from being in contact with the lower electrode 111. Furthermore, the insulating layer 126 can separate the organic compound layers of the light-emitting devices, thereby inhibiting crosstalk between the light-emitting devices. Crosstalk is a phenomenon in which light is unintentionally emitted from a light-emitting device.

FIG. 4A illustrates that the top surface of the insulating layer 126 is substantially aligned or aligned with the top surface of the organic compound layer 112. The positional relation is preferably satisfied, in which case the formation surface of the common electrode 113 is flat to inhibit the common electrode 113 from being cut.

Although not illustrated in FIG. 4A, the top surface of the insulating layer 126 may be positioned above the top surface of the organic compound layer 112 in order that the common electrode 113 is not cut. In this case, it is preferable that an end portion of the insulating layer 126 is gradually reduced in thickness toward the center of the organic compound layer 112. The shape with the gradually reduced thickness is sometimes referred to as a tapered shape.

Although not illustrated in FIG. 4A, a center portion of the insulating layer 126 is preferably higher than the end portion of the insulating layer 126 and further preferably includes a region rising above the end portion. Providing the common electrode 113 over the insulating layer 126 having such a shape is preferable to inhibit the common electrode 113 from being cut.

Although FIG. 4A illustrates a structure in which the second wiring layer 151b of the auxiliary wiring 151 includes a region in contact with the bottom of the common electrode 113, any structure can be employed as long as the auxiliary wiring 151 is electrically connected to the common electrode 113.

### [Layout of Auxiliary Wiring]

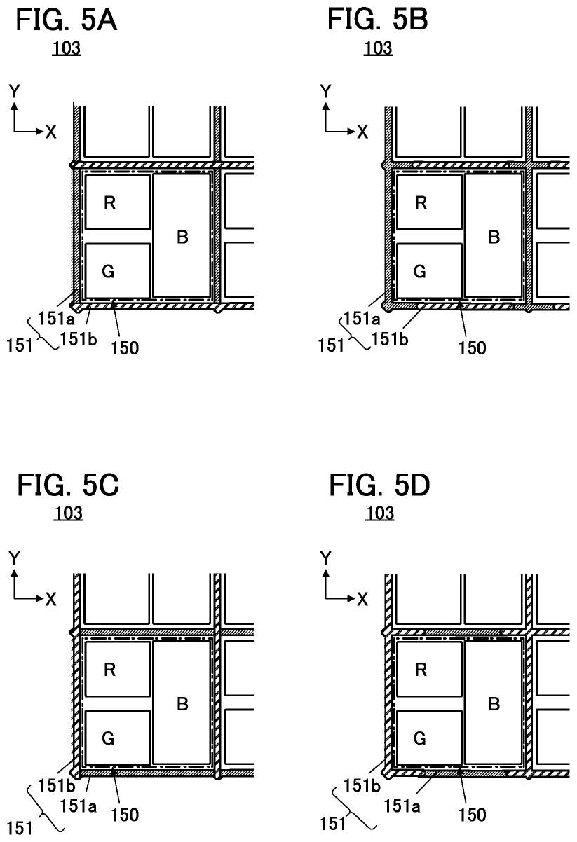

The auxiliary wiring 151 of one embodiment of the present invention has a feature of including at least two or more wiring layers; layout examples of the first wiring layer 151a and the second wiring layer 151b are described with reference to FIG. 5 and the like. Although the subpixels (R, G, and B) are illustrated in FIG. 5 and the like in accordance with FIG. 4B, the lower electrodes 111 are omitted.

In the pixel portion 103 illustrated in FIG. 5A, the auxiliary wiring 151 has a lattice shape in a top view and includes the first wiring layer 151a extending in the Y direction and the second wiring layer 151b extending in the X direction. Note that FIG. 5A does not illustrate a contact hole positioned in a region where the first wiring layer 151a and the second wiring layer 151b intersect with each other.

Either one of the first wiring layer 151a and the second wiring layer 151b may be formed in the same layer as the lower electrodes 111, or both of them may be formed in a layer different from that of the lower electrodes 111.

In the pixel portion 103 illustrated in FIG. 5A, the first wiring layer 151a and the second wiring layer 151b are both positioned between the pixels. The pixel portion 103 is used in a high-resolution display apparatus.

FIG. 5B illustrates an auxiliary wiring 151 in which the second wiring layer 151b has shorter length than that illustrated in FIG. 5A. The first wiring layer 151a includes a region extending in the X direction for the length by which the second wiring layer 151b is shortened. The shortened second wiring layer 151b has a length such that one end overlaps with the subpixel G and the other end overlaps with the subpixel B. The other structures are similar to those in FIG. 5A.

FIG. 5C illustrates an auxiliary wiring 151 in which the first wiring layer 151a illustrated in FIG. 5A is a second wiring layer 151b and the second wiring layer 151b illustrated in FIG. 5A is a first wiring layer 151a. The other structures are similar to those in FIG. 5A.

FIG. 5D illustrates an auxiliary wiring 151 in which the first wiring layer 151a has shorter length than that illustrated in FIG. 5C. The second wiring layer 151b includes a region extending in the X direction for the length by which the first wiring layer 151a is shortened. The shortened first wiring layer 151a has a length such that one end overlaps with the subpixel G and the other end overlaps with the subpixel B. The other structures are similar to those in FIG. 5C.

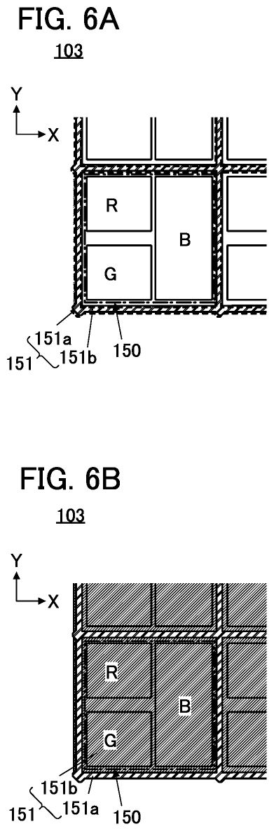

FIG. 5A illustrates the auxiliary wiring 151 in which the first wiring layer 151a and the second wiring layer 151b have the same shape. In FIG. 6A, the first wiring layer 151a is denoted by dotted line. The other structures are similar to those in FIG. 5A.

FIG. 6B illustrates the auxiliary wiring 151 including the first wiring layer 151a having a larger area than the second wiring layer 151b. Formed in a layer different from the layer of the lower electrodes 111, the first wiring layer 151a can be formed in a large area. The other structures are similar to those in FIG. 5A.

In this manner, the auxiliary wiring 151 of one embodiment of the present invention includes the first wiring layer 151a and the second wiring layer 151b, and accordingly can have various embodiments. In addition, electrically connecting the auxiliary wiring 151 to the common electrode can sufficiently inhibit the voltage drop of the common electrode. Moreover, a high-resolution pixel portion can be used in the display apparatus of one embodiment of the present invention.

The auxiliary wiring 151 may be used for a bottom-emission structure and a dual-emission structure. In this case, the cross-sectional structure of the auxiliary wiring 151 described in the above embodiment with reference to FIG. 1 to FIG. 3 and the like can be employed. In the bottom-emission structure and the dual-emission structure, light is emitted downwardly through the lower electrode 111; thus, the first wiring layer 151a provided below the lower electrode 111 preferably has a lattice shape overlapping with the gap between the subpixels or the gap between the pixels, or a smaller area than the lattice shape. Moreover, the second wiring layer 151b provided below the lower electrode 111 preferably has a lattice shape overlapping with the gap between the subpixels or the gap between the pixels, or a smaller area than the lattice shape.

### <Specific Example of Display Apparatus>

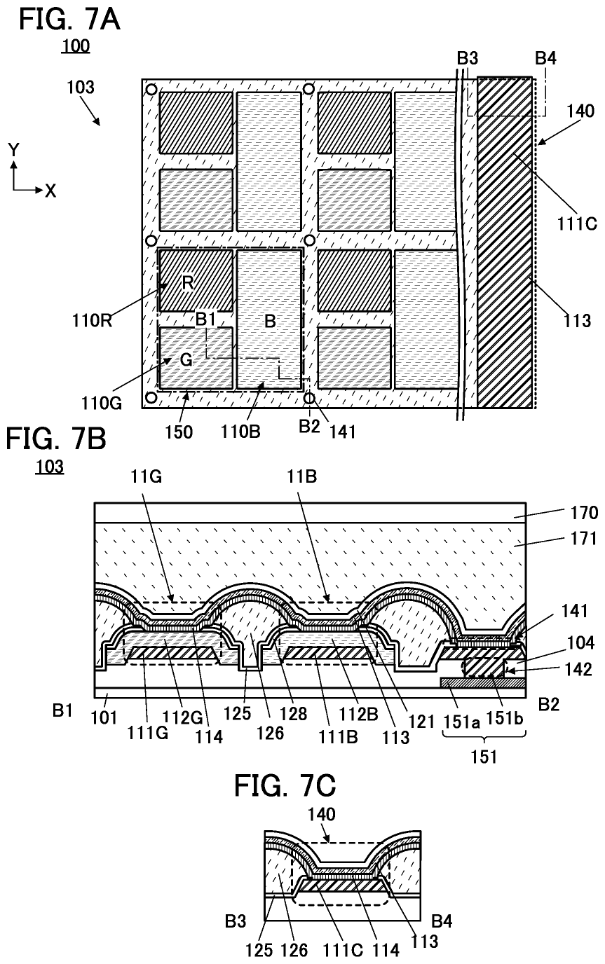

A specific example of a display apparatus having a top-emission structure illustrated in FIG. 4 and the like is described with reference to FIG. 7A to FIG. 7C. A display apparatus 100 includes the pixel portion 103 and a connection portion 140. The pixel portion 103 includes a plurality of pixels 150. The pixel 150 includes a plurality of subpixels 110: for example, the subpixel 110R including the light-emitting device 11R exhibiting red, the subpixel 110G including the light-emitting device 11G exhibiting green, and the subpixel 110B including the light-emitting device 11B exhibiting blue. The pixel region 103 includes a contact hole 141. The contact hole 141 is selectively provided; for example, the contact hole 141 can be provided in a region corresponding to the periphery of the pixel 150 and can be provided in regions corresponding to four corners of the region of the pixel 150.

In FIG. 7A, regions corresponding to the light-emitting device 11R, the light-emitting device 11G, and the light-emitting device 11B are denoted by R, G, and B, respectively. The arrangement in FIG. 7A is similar to that illustrated in FIG. 4B and the like, and is regular.

As the light-emitting device 11, an element such as an OLED (Organic Light Emitting Diode) or a QLED (Quantum-dot Light Emitting Diode) is preferably used. Examples of a light-emitting substance contained in the light-emitting device include a substance that exhibits fluorescence (a fluorescent material), a substance that exhibits phosphorescence (a phosphorescent material), an inorganic compound (a quantum dot material or the like), and a substance that exhibits thermally activated delayed fluorescence (a thermally activated delayed fluorescent (TADF) material).

The connection portion 140 illustrated in FIG. 7A is a region including the connection electrode 111C electrically connected to the common electrode 113. The common electrode 113 preferably extends beyond the end of the pixel portion 103 to the connection portion 140. In FIG. 7A, the common electrode 113 extended to the connection portion 140 is indicated by dotted line. The connection electrode 111C is supplied with a potential to be supplied to the common electrode 113. When a voltage drop due to the common electrode 113 occurs, the value of the potential varies. The display apparatus of this embodiment preferably includes the auxiliary wiring 151 at least in the pixel portion 103, in which case variations in the potential can be inhibited. The auxiliary wiring 151 can also be provided in the connection portion 140 in addition to the pixel portion 103.

The connection electrode 111C can be provided along the periphery of the pixel portion 103. For example, the connection electrode 111C may be provided along one side of the periphery of the pixel portion 103 or may be provided along two or more sides of the periphery of the pixel portion 103. That is, in the case where the top surface of the pixel portion 103 has a rectangular shape, the top surface of the connection electrode 111C can have a band shape along one side of the periphery, an L shape along two sides of the periphery, a U-like shape along three sides of the periphery, a quadrangular shape along four sides of the periphery, or the like.

FIG. 7B and FIG. 7C illustrate cross-sectional views taken along dashed-dotted line B1-B2 and dashed-dotted line B3-B4 in FIG. 7A. FIG. 7B illustrates a cross-sectional view of the light-emitting device 11G, the light-emitting device 111B, and the auxiliary wiring 151, and FIG. 7C illustrates a cross-sectional view of the connection electrode 111C.

FIG. 7B is a cross-sectional view of the contact hole 141. The contact hole 141 is formed in the insulating layer 126. The second wiring layer 151b and the common electrode 113 can be electrically connected to each other through the contact hole 141.

Although not illustrated in FIG. 7A, the insulating layer 104 includes a contact hole 142. The second wiring layer 151b and the first wiring layer 151a can be electrically connected to each other through the contact hole 142. The contact hole 142 may be formed in a region overlapping with the contact hole 141 or in a region not overlapping with the contact hole 141. In the case where the thickness of the insulating layer 126 is larger than that of the insulating layer 104, the size (e.g., the width in a cross-sectional view) of the contact hole 141 is preferably larger than the size (e.g., the width in a cross-sectional view) of the contact hole 142.

As illustrated in FIG. 7B, the edge surface of the organic compound layer 112B is perpendicular or substantially perpendicular, which is preferable in terms of easy processing of the contact hole 141. The taper angle of the end surface of the organic compound layer 112B is preferably greater than or equal to 45° and less than 90°. It is preferable that the taper angle of the end surfaces of the other organic compound layers is also greater than or equal to 45° and less than 90°.

Note that in this specification and the like, the taper angle refers to an inclination angle formed by the side surface and the bottom surface of a specific layer when the layer is observed from the direction perpendicular to the cross section (e.g., the plane perpendicular to the surface of the substrate). In the case where the bottom surface is unclear, a tilt angle can be determined using the surface of the substrate.

Although not illustrated in FIG. 7B, the light-emitting device 11R includes the lower electrode 111R, the organic compound layer 112R, a common layer 114, and the common electrode 113. The light-emitting device 11G illustrated in FIG. 7B includes the lower electrode 111G, the organic compound layer 112G, the common layer 114, and the common electrode 113. The light-emitting device 11B illustrated in FIG. 7B includes the lower electrode 111B, the organic compound layer 112B, the common layer 114, and the common electrode 113. A functional layer that can be used for the common layer 114 is an electron-injection layer, for example. Note that the lower electrode 111 is an electrode electrically connected to a transistor and is referred to as a pixel electrode in some cases. Furthermore, the lower electrode 111 functions as one of an anode and a cathode of the light-emitting device and is referred to as an anode or a cathode in some cases.

The organic compound layer 112R contains at least a light-emitting organic compound that emits light with intensity in the red wavelength range. The organic compound layer 112G contains at least a light-emitting organic compound that emits light with intensity in the green wavelength range. The organic compound layer 112B contains at least a light-emitting organic compound that emits light with intensity in the blue wavelength range. A layer containing a light-emitting organic compound can be referred to as a light-emitting layer.

The organic compound layer 112 and the common layer 114 can each independently include one or two or more selected from an electron-injection layer, an electron-transport layer, a light-emitting layer, a hole-injection layer, and a hole-transport layer. The electron-injection layer, the electron-transport layer, the light-emitting layer, the hole-injection layer, and the hole-transport layer may be referred to as functional layers. “Including two or more layers” includes the case where two or more functional layers different from each other are included in combination and the case where two or more functional layers that are the same functional layers but contain different materials are included in combination. Specific materials usable for the functional layers will be described later.

In this embodiment, the organic compound layer 112 has a stacked-layer structure in which a hole-injection layer, a hole-transport layer, a light-emitting layer, and an electron-transport layer are stacked in this order from the lower electrode 111 side, and the common layer 114 includes an electron-injection layer.

Note that the functional layers only need to achieve their respective functions, and do not necessarily contain organic compounds. For example, it is possible to use a film only containing an inorganic compound or an inorganic substance as the electron-injection layer or the like.

the lower electrode 111R, the lower electrode 111G, and the lower electrode 111B are provided for the respective light-emitting devices. Each of the common electrode 113 and the common layer 114 is provided as a continuous layer shared by the light-emitting devices. A display apparatus having a top-emission structure can be obtained by using a conductive film having a reflective property as the lower electrode 111 and using a conductive film having a light-transmitting property with respect to visible light as the common electrode 113.

The lower electrode 111 preferably has an end portion with a tapered shape. An end portion of the organic compound layer 112 is positioned in a region beyond the lower electrode 111; when the end portion of the lower electrode 111 has a tapered shape, the organic compound layer 112 has a shape along the tapered shape. The side surface of the lower electrode 111 having a tapered shape can improve coverage with the organic compound layer or the like.

The organic compound layer 112 is processed by a photolithography method. Accordingly, an angle between the end portion of the organic compound layer 112 and its formation surface may be close to 90°. The end portion of the organic compound layer 112 is positioned in a region beyond the end portion of the lower electrode 111.

An insulating layer 126 is preferably provided between two adjacent light-emitting devices. The insulating layer 126 is positioned between the two adjacent light-emitting devices and is provided to fill at least a space between two adjacent organic compound layers 112. The insulating layer 126 further preferably includes a region overlapping with the end portion of the organic compound layer 112. That is, the end portion of the insulating layer 126 can be positioned over the organic compound layer 112, and the level difference between the upper portion and the end portion of the insulating layer 126 can be made small. An increased level difference between the upper portion and the end portion of the insulating layer 126 makes the insulating layer 126 easily pealed in some cases; accordingly the difference is preferably small.

The upper portion of the insulating layer 126 preferably has a smooth projecting shape. An upper portion having a projecting shape can also be referred to as a shape in which the center portion of the insulating layer 126 rises above the end portion.

At least the common layer 114 and the common electrode 113 are provided to cover the insulating layer 126, whereby the common layer 114 and the common electrode 113 can be inhibited from being cut.

An insulating layer 125 is preferably provided to be in contact with the side surface of the organic compound layer 112. The insulating layer 125 is positioned between the insulating layer 126 and the organic compound layer 112 to function as a protective film for preventing contact between the insulating layer 126 and the organic compound layer 112. In the case where the insulating layer 126 is in contact with the organic compound layer 112, the organic compound layer 112 might be dissolved by an organic solvent or the like used in the formation or processing of the insulating layer 126. In view of this, the insulating layer 125 is provided between the organic compound layer 112 and the insulating layer 126 as described in this embodiment to protect the organic compound layer 112.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film, an aluminum nitride film, and the like. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film formed by an atomic layer deposition (ALD) method is used as the insulating layer 125, the insulating layer 125 having few pinholes and an excellent function of protecting the organic compound layer can be formed.

Note that in this specification and the like, an oxynitride refers to a material that contains more oxygen than nitrogen, and a nitride oxide refers to a material that contains more nitrogen than oxygen. For example, silicon oxynitride refers to a material in which an oxygen content is higher than a nitrogen content, and a silicon nitride oxide refers to a material in which a nitrogen content is higher than an oxygen content.

The insulating layer 125 can be formed by a sputtering method, a chemical vapor deposition (CVD) method, a pulsed laser deposition (PLD) method, an ALD method, or the like. The insulating layer 125 is preferably formed by an ALD method achieving good coverage.

An insulating layer containing an organic material can be suitably used as the insulating layer 126. For the insulating layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the insulating layer 126, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used.

Moreover, for the insulating layer 126, a photosensitive resin can be used. A photoresist may be used as the photosensitive resin. As the photosensitive resin, a positive material or a negative material can be used.

In the case where a material having photosensitivity is used for the insulating layer 126, light exposure and development are performed, whereby the processed insulating layer 126 can be formed. The surface of the processed insulating layer 126 may have a rounded shape or an uneven shape. Etching may be performed so that the surface level of the processed insulating layer 126 is adjusted. The insulating layer 126 is processed by ashing using oxygen plasma, so that the surface level can be adjusted.

The insulating layer 126 preferably contains a material absorbing visible light. For example, the insulating layer 126 itself may be made of a material absorbing visible light, or the insulating layer 126 may contain a pigment absorbing visible light. For example, the insulating layer 126 can be formed using a resin that can be used as a color filter transmitting red, blue, or green light and absorbing light of the other colors; or a resin that contains carbon black as a pigment and functions as a black matrix.

It is preferable that the top surface of the insulating layer 126 have a portion whose level is higher than the level of the top surface of the organic compound layer 112. Accordingly, light emitted from the light-emitting device 11 in the oblique direction can be absorbed, and the insulating layer 126 can further exert an effect of inhibiting stray light along with an auxiliary electrode.

The insulating layer 126 can be formed by, for example, a wet process such as spin coating, dipping, spray coating, ink-jetting, dispensing, screen printing, offset printing, doctor blade coating, slit coating, roll coating, curtain coating, or knife coating. Specifically, the organic insulating film to be the insulating layer 126 is preferably formed by spin coating.

After the insulating layer 126 is formed, heat treatment is preferably performed in the air at a temperature higher than or equal to 85° C. and lower than or equal to 120° C. for longer than or equal to 45 minutes and shorter than or equal to 100 minutes. The insulating layer 126 can be dehydrated or degassed.

Between the insulating layer 125 and the insulating layer 126, a reflective film (e.g., a metal film containing one or more selected from silver, palladium, copper, titanium, aluminum, and the like) may be provided. For example, after the insulating layer 125 is formed, the reflective film can be formed. With the reflective film, light emitted from the light-emitting layer can be reflected. This can increase the light extraction efficiency.

As illustrated in FIG. 7B, an insulating layer 128 may be provided between the insulating layer 125 and the top surface of the organic compound layer 112. Part of a protective layer (also referred to as a mask layer) for protecting the organic compound layer 112 during etching of the organic compound layer 112 remains to be the insulating layer 128. For the insulating layer 128, the material usable for the insulating layer 125 is preferably used. It is particularly preferable to use the same material for the insulating layer 128 and the insulating layer 125 to facilitate processing. For example, both the insulating layer 128 and the insulating layer 125 preferably include an aluminum oxide film, a hafnium oxide film, or a silicon oxide film.

The insulating layer 125, the insulating layer 126, and the insulating layer 128 are insulating layers positioned between the light-emitting devices and may be collectively referred to as an insulating stack. Since the common layer 114 and the common electrode 113 are provided over the insulating stack, an end portion of the insulating stack has a tapered shape to prevent disconnection of the common layer 114 and the common electrode 113. In order that the end portion of the insulating stack has a tapered shape, an end portion of the insulating layer 125 may have a tapered shape, the end portion of the insulating layer 126 may have a tapered shape, an end portion of the insulating layer 128 may have a tapered shape, or the end portions of the insulating layer 125, the insulating layer 126, and the insulating layer 128 may each have a tapered shape. In the case where a plurality of insulating layers form a tapered shape, end portions of the insulating layers are preferably continuously formed to have a tapered shape.

Furthermore, a center portion of the top surface of the insulating stack preferably has a rounded shape. That is, the center portion of the insulating stack is shaped to rise above the end portion. To obtain the above shape, the insulating layer 126 positioned in the uppermost layer of the insulating stack is preferably formed using an organic material.

Furthermore, the end portion of the insulating stack can have various shapes. For example, the insulating layer 125 positioned as a lower layer of the insulating stack may protrude from the insulating layer 126. In this case, part of an upper portion of the insulating layer 125 is removed at the time of processing of the insulating layer 126 in some cases. Removing part of the upper portion of the insulating layer 125 protruded from the insulating layer 126 has an effect of preventing the common layer 114 and the common electrode 113 from being cut.

The insulating layer 128 may protrude from the insulating layer 126. In this case, part of the upper portion of the insulating layer 128 is removed at the time of processing of the insulating layer 126 in some cases. Removing part of the upper portion of the insulating layer 128 protruded from the insulating layer 126 has an effect of preventing the common layer 114 and the common electrode 113 from being cut.

When the insulating layer 128 protrudes from the insulating layer 126, the end portion of the insulating layer 125 positioned below the insulating layer 128 is preferably aligned or substantially aligned with the end portion of the insulating layer 128.

As illustrated in FIG. 7B, a protective layer 121 is provided over the common electrode 113. The protective layer 121 has a function of preventing diffusion of impurities into the light-emitting elements from above.

The protective layer 121 can have, for example, a single-layer structure or a stacked-layer structure at least including an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as an indium gallium oxide or an indium gallium zinc oxide may be used for the protective layer 121.

The protective layer 121 is bonded to a substrate 170 with an adhesive layer 171. For the adhesive layer 171, a variety of curable adhesives such as a reactive curable adhesive, a thermosetting adhesive, an anaerobic adhesive, and a photocurable adhesive such as an ultraviolet curable adhesive can be used. As the adhesive layer 171, an adhesive sheet or the like may be used.

In the connection portion 140 illustrated in FIG. 7C, an opening portion is provided in the insulating layer 125 and the insulating layer 126 over the connection electrode 111C. The connection electrode 111C and the common electrode 113 are electrically connected to each other through the opening portion. The opening portion for electrically connecting the connection electrode 111C and the common electrode 113 may be provided in any of the insulating layers.

FIG. 7C illustrates a structure in which the common layer 114 is provided over the connection electrode 111C and the common electrode 113 is provided over the common layer 114. In the case where a carrier-injection layer such as an electron-injection layer is used as the common layer 114, for example, the resistivity of a material used for the common layer 114 is sufficiently low; accordingly, the connection electrode 111C can be electrically connected to the common electrode 113 through the common layer 114. Thus, the common electrode 113 and the common layer 114 can be formed using the same mask (also referred to as an area mask, a rough metal mask, or the like to be distinguished from a fine metal mask), leading to a reduction in manufacturing cost. Needless to say, in the connection portion 140, the connection electrode 111C may include a region in contact with the common electrode 113.

A structure example of a display apparatus whose structure is partly different from that of the above-described structure example is described below. In the following description, portions similar to the specific examples described above are denoted by the same reference numerals as those in the specific examples, and the description thereof is not repeated in some cases.

In the display apparatus described as the specific example, at least organic compound layers are separated. With this structure, crosstalk due to leakage current is inhibited, so that an image with extremely high display quality can be displayed. Moreover, both a high aperture ratio and high resolution can be achieved. The display apparatus of one embodiment of the present invention can be used in an ultra-sized display of greater than or equal to 40 inches, greater than or equal to 100 inches, and further greater than or equal to 100 inches.

This embodiment can be combined with the other embodiments as appropriate. In this specification, in the case where a plurality of structure examples are described in one embodiment, the structure examples can be combined as appropriate.

### Embodiment 3

In this embodiment, layouts of subpixels will be described.

### <Layout>

There is no particular limitation on the arrangement of subpixels, and stripe arrangement, S-stripe arrangement, matrix arrangement, delta arrangement, Bayer arrangement, PenTile arrangement, or the like can be used.

Examples of the top surface shape of the subpixel include polygons such as a triangle, a tetragon (including a rectangle and a square), and a pentagon; polygons with rounded corners; an ellipse; and a circle. The top surface shape of a subpixel herein refers to a light-emitting region of a light-emitting device.

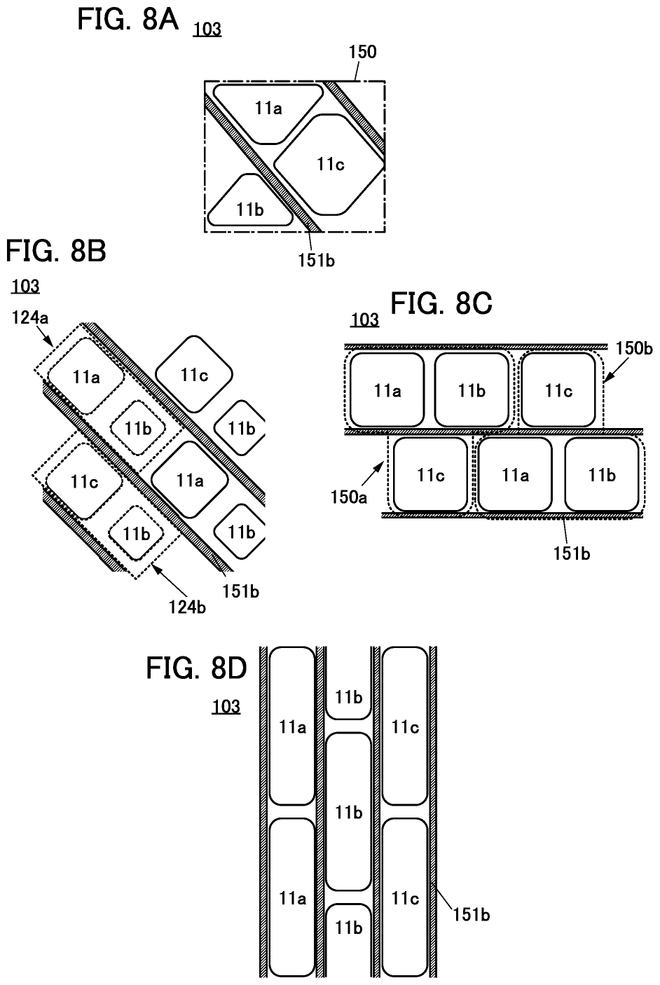

The pixel portion 103 illustrated in FIG. 8A includes the second wiring layer 151b as part of the auxiliary wiring, and the pixel 150 includes a light-emitting device 11a having a top surface shape with a rough trapezoidal shape with rounded corners, a light-emitting device 11b having a top surface shape with a rough triangle shape with rounded corners, and a light-emitting device 11c having a top surface shape with a rough tetragonal or rough hexagonal shape with rounded corners. Moreover, the light-emitting device 11a has a larger light-emitting area than the light-emitting device 11b. In this manner, the shapes and sizes of the light-emitting devices can be determined independently. For example, the size of a light-emitting device with higher reliability can be smaller.

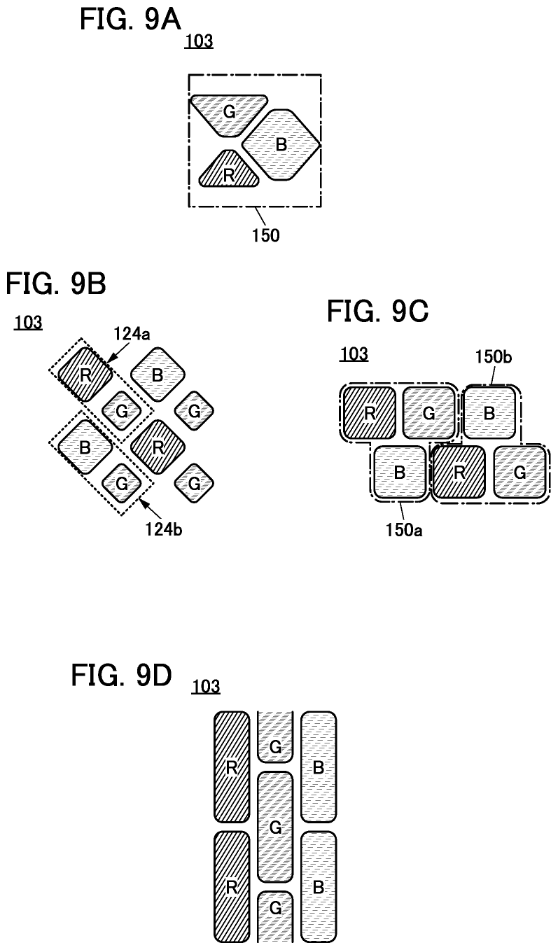

In the pixel portion 103 illustrated in FIG. 8A, as illustrated in FIG. 9A, the light-emitting device 11a can be a green-light-emitting device G, the light-emitting device 11b can be a red-light-emitting device R, and the light-emitting device 11c can be a blue-light-emitting device B.

The pixel portion 103 illustrated in FIG. 8B includes the second wiring layer 151b as part of the auxiliary wiring, and PenTile arrangement is used for the arrangement of subpixels. In the PenTile arrangement, a pair 124a of a subpixel including the light-emitting device 11a and the light-emitting device 11b and a pair 124b of a subpixel including the light-emitting device 11b and the light-emitting device 11c are alternately laid out.

In the pixel portion 103 illustrated in FIG. 8B, as illustrated in FIG. 9B, the light-emitting device 11a can be the red-light-emitting device R, the light-emitting device 11b can be the green-light-emitting device G, and the light-emitting device 11c can be the blue-light-emitting device B.

The pixel portion 103 illustrated in FIG. 8C includes the second wiring layer 151b as part of the auxiliary wiring, and a pixel 150a and a pixel 150b employ delta arrangement. In the delta arrangement, the pixel 150a includes two light-emitting devices (the light-emitting device 11a and the light-emitting device 11b) in the upper row (first row) and one light-emitting device (the light-emitting device 11c) in the lower row (second row). The pixel 150b includes one light-emitting device (the light-emitting device 11c) in the upper row (first row) and two light-emitting devices (the light-emitting device 11a and the light-emitting device 11b) in the lower row (second row).

In the pixel portion 103 illustrated in FIG. 8C, as illustrated in FIG. 9C, the light-emitting device 11a may be the red-light-emitting device R, the light-emitting device 11b may be the green-light-emitting device G, and the light-emitting device 11c may be the blue-light-emitting device B.

FIG. 8D illustrates an example in which the pixel portion 103 includes the second wiring layer 151b as part of the auxiliary wiring and the light-emitting devices of different colors are laid out in a zigzag manner. In the zigzag layout, positions of the top sides of two light-emitting devices arranged in the column direction (e.g., the light-emitting device 11a and the light-emitting device 11b or the light-emitting device 11b and the light-emitting device 11c) are shifted in a top view.

In the pixel portion 103 illustrated in FIG. 8D, as illustrated in FIG. 9D, the light-emitting device 11a may be the red-light-emitting device R, the light-emitting device 11b may be the green-light-emitting device G, and the light-emitting device 11c may be the blue-light-emitting device B.

In a photolithography method, as a pattern to be formed by processing becomes finer, the influence of light diffraction becomes more difficult to ignore; accordingly, the fidelity in transferring a resist mask pattern by light exposure is degraded, and it becomes difficult to process a resist mask into a desired shape. Thus, a pattern with rounded corners is likely to be formed even when a resist mask pattern is rectangular. Consequently, the top surface of a light-emitting device may have a polygonal shape with rounded corners, an elliptical shape, a circular shape, or the like.

Furthermore, in the method for manufacturing the display apparatus of one embodiment of the present invention, the organic compound layer is processed with the use of a resist mask. A resist mask formed over the organic compound layer needs to be cured at a temperature lower than the upper temperature limit of the organic compound layer. Thus, curing for the formation of the resist mask is insufficient in some cases depending on the upper temperature limit of the material of the organic compound layer and the curing temperature of a resist material. An insufficiently cured resist mask may have a shape different from a desired shape by processing. As a result, the top surface shape of the organic compound layer may have a polygonal shape with rounded corners, an elliptical shape, a circular shape, or the like. For example, when a resist mask whose top surface shape is square is intended to be formed, a resist mask whose top surface shape is circular may be formed, and the top surface shape of the organic compound layer may be circular.

To obtain a desired top surface shape of the organic compound layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

This embodiment can be combined with the other embodiments as appropriate. In this specification, in the case where a plurality of structure examples are described in one embodiment, the structure examples can be combined as appropriate.

### Embodiment 4

In this embodiment, materials that can be used for a light-emitting device, for example, will be described.

### [Light-Emitting Device]

In the light-emitting device, a conductive film having a light-transmitting property is preferably used as the electrode through which light is extracted, and a conductive film that reflects visible light is preferably used as the electrode through which light is not extracted. A conductive film that transmits visible light may be used also for the electrode through which light is not extracted. In this case, the electrode is preferably laid out between the conductive film that reflects visible light and the organic compound layer. That is, light emitted from the light-emitting device is reflected by the conductive film that reflects visible light and extracted from the display apparatus.

As a material that forms the electrodes of the light-emitting device, a metal, an alloy, an electrically conductive compound, a mixture thereof, and the like can be used as appropriate. Specific examples include an indium tin oxide, an In—Si—Sn oxide, an indium zinc oxide, an In—W—Zn oxide, an alloy containing aluminum (also referred to as an aluminum alloy) such as an alloy of aluminum, nickel, and lanthanum (also referred to as an Al—Ni—La alloy), and an alloy of silver, palladium, and copper (also referred to as Ag—Pd—Cu or APC). It is also possible to use a metal such as aluminum, titanium, chromium, manganese, iron, cobalt, nickel, copper, gallium, zinc, indium, tin, molybdenum, tantalum, tungsten, palladium, gold, platinum, silver, yttrium, or neodymium, or an alloy containing an appropriate combination of any of these metals. It is also possible to use an element belonging to Group 1 or Group 2 of the periodic table, which is not exemplified above (e.g., lithium, cesium, calcium, or strontium), a rare earth metal such as europium or ytterbium, an alloy containing an appropriate combination of any of these, graphene, or the like.

Among the above materials, a material which can release holes can be used as an anode, and a material which can release electrons can be used as a cathode.

The light-emitting device preferably employs a microcavity structure. Accordingly, one of the pair of electrodes of the light-emitting device preferably includes an electrode having a transmitting property and a reflecting property with respect to visible light (a semi-transmissive and semi-reflective electrode), and the other is preferably an electrode having a reflecting property with respect to visible light (a reflective electrode). When the light-emitting device has a microcavity structure, light emitted from the light-emitting device is resonated between the pair of electrodes, whereby the emission spectrum of the light can be narrowed and the light can be intensified.

When the microcavity structure is employed, light-emitting devices of red, green, and blue differ in the distance between the pair of electrodes.

Note that the semi-transmissive and semi-reflective electrode can have a stacked-layer structure of a reflective electrode and an electrode having a transmitting property with respect to visible light (also referred to as a transparent electrode).

The transparent electrode has a light transmittance higher than or equal to 40%. For example, an electrode having a visible light (light with a wavelength greater than or equal to 400 nm and less than 750 nm) transmittance higher than or equal to 40% is preferably used in the light-emitting device. The semi-transmissive and semi-reflective electrode has a visible light reflectance of higher than or equal to 10% and lower than or equal to 95%, and preferably higher than or equal to 30% and lower than or equal to 80%. The reflective electrode has a visible light reflectance of higher than or equal to 40% and lower than or equal to 100%, and preferably higher than or equal to 70% and lower than or equal to 100%.

The organic compound layer of the light-emitting device includes at least a light-emitting layer. The light-emitting layer contains a light-emitting material (also referred to as a light-emitting substance). The light-emitting layer can include one or more kinds of light-emitting substances. As the light-emitting substance, a substance that exhibits an emission color of blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (a host material, an assist material, and the like) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting device can be achieved at the same time.

In addition to the light-emitting layer, the organic compound layer 112 may further include a layer containing any of a substance having a high hole-injection property, a substance having a high hole-transport property, a hole-blocking material, a substance having a high electron-transport property, a substance having a high electron-injection property, an electron-blocking material, a substance having a bipolar property (a substance having a high electron-transport property and a high hole-transport property), and the like.

Either a low molecular compound or a high molecular compound can be used in the light-emitting device, and an inorganic compound may also be contained. Each layer included in the light-emitting device can be formed by a method such as an evaporation method (including a vacuum evaporation method), a transfer method, a printing method, an inkjet method and a coating method.

For example, the organic compound layer 112 may include one or more of a hole-injection layer, a hole-transport layer, a hole-blocking layer, an electron-blocking layer, an electron-transport layer, and an electron-injection layer.

As the common layer 114, one or more of a hole-injection layer, a hole-transport layer, a hole-blocking layer, an electron-blocking layer, an electron-transport layer, and an electron-injection layer can be used. For example, a carrier-injection layer (a hole-injection layer or an electron-injection layer) may be formed as the common layer 114. Note that the light-emitting device does not necessarily include the common layer 114.

The hole-injection layer is a layer injecting holes from an anode to a hole-transport layer and containing a material having a high hole-injection property. Examples of the material having a high hole-injection property include an aromatic amine compound and a composite material containing a hole-transport material and an acceptor material (electron-accepting material).

The hole-transport layer is a layer transporting holes, which are injected from the anode by the hole-injection layer, to the light-emitting layer. The hole-transport layer is a layer containing a hole-transport material. As the hole-transport material, a substance having a hole mobility higher than or equal to 10⁻⁶ cm²/Vs is preferable. Note that other substances can also be used as long as they have a property of transporting more holes than electrons. As the hole-transport material, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-blocking layer is provided in contact with the light-emitting layer. The electron-blocking layer has a hole-transport property and contains a material capable of blocking electrons. Among the above hole-transport materials, a material having an electron-blocking property can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from a cathode by the electron-injection layer, to the light-emitting layer. The electron-transport layer is a layer containing an electron-transport material. A material with an electron mobility higher than or equal to 1×10⁻⁶ cm²/Vs is preferable as the electron-transport material. Note that other substances can also be used as long as they have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a it-electron deficient heteroaromatic compound such as a nitrogen-containing heteroaromatic compound.

For example, a compound having an unshared electron pair and an electron deficient heteroaromatic ring can be used as another electron-transport material. Specifically, it is possible to use a compound having at least one of a pyridine ring, a diazine ring (a pyrimidine ring, a pyrazine ring, and a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In addition, in general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-bidi(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

The hole-blocking layer is provided in contact with the light-emitting layer. The hole-blocking layer has an electron-transport property and contains a material capable of blocking holes. Among the above electron-transport materials, a material having a hole-blocking property can be used for the hole-blocking layer.

The hole-blocking layer has an electron-transport property, and thus can also be referred to as an electron-transport layer. Among the electron-transport layers, a layer having a hole-blocking property can also be referred to as a hole-blocking layer.

The electron-injection layer is a layer injecting electrons from a cathode to the electron-transport layer and containing a material having a high electron-injection property. As the material having a high electron-injection property, an alkali metal, an alkaline earth metal, or a compound thereof can be used. As the material having a high electron-injection property, a composite material containing an electron-transport material and a donor material (an electron-donating material) can also be used.

Examples of the alkali metal or the alkaline earth metal include lithium, cesium, and magnesium and examples of the compound include lithium fluoride (LiF), cesium fluoride (CsF), calcium fluoride (CaFx, X is a given number), lithium oxide (LiOx, X is a given number), and cesium carbonate.

Alternatively, an organic compound can be used as the material usable for the electron-injection layer. Examples of the organic compound include 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), 4,7-diphenyl-1,10-phenanthroline (abbreviation: BPhen), 2,9-di(naphthalen-2-yl)-4,7-diphenyl-1,10-phenanthroline (abbreviation: NBPhen), and the like.

The organic compound may include a dopant. A metal is used as the dopant; for example, silver (Ag) or ytterbium (Yb) can be used.

As the material usable for the electron-injection layer, a composite material containing the above alkali metal or alkaline earth metal and the above organic compound can also be used.

The electron-injection layer may have a stacked-layer structure of two or more layers. The above materials can be combined as appropriate for the stacked-layer structure. For example, it is possible to employ a structure where lithium fluoride is used for a first layer and ytterbium is used for a second layer.

Alternatively, for the electron-injection layer, the above electron-transport materials may be used.

This embodiment can be combined with the other embodiments as appropriate. In this specification, in the case where a plurality of structure examples are described in one embodiment, the structure examples can be combined as appropriate.

### Embodiment 5

In this embodiment, a display apparatus will be described.

### [Structure Example of Display Apparatus]

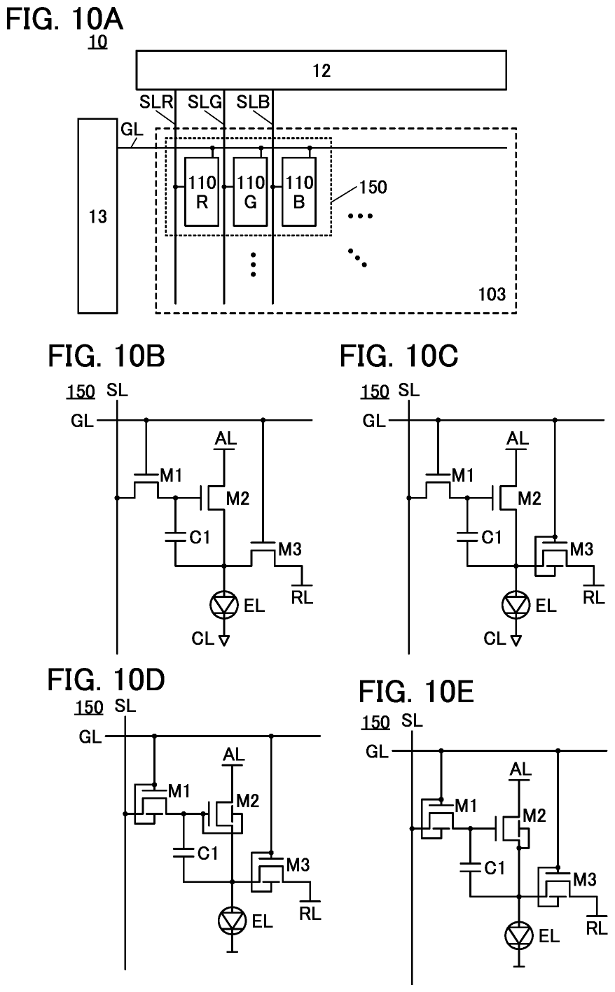

FIG. 10A illustrates a block diagram of a display apparatus 10. The display apparatus 10 includes a pixel portion 103, a driver circuit portion 12, a driver circuit portion 13, and the like.

The pixel portion 103 includes a plurality of pixels 150 laid out in a matrix. The pixel 150 includes the subpixel 110R, the subpixel 110G, and the subpixel 110B. The subpixel 110R, the subpixel 110G, and the subpixel 110B each include a light-emitting device functioning as a display device.

The pixel 150 is electrically connected to a wiring GL, a wiring SLR, a wiring SLG, and a wiring SLB. The wiring SLR, the wiring SLG, and the wiring SLB are electrically connected to the driver circuit portion 12. The wiring GL is electrically connected to the driver circuit portion 13. The driver circuit portion 12 functions as a source line driver circuit (also referred to as a source driver), and the driver circuit portion 13 functions as a gate line driver circuit (also referred to as a gate driver). The wiring GL functions as a gate line, and the wiring SLR, the wiring SLG, and the wiring SLB each function as a source line.

The subpixel 110R includes a light-emitting device that emits red light. The subpixel 110G includes a light-emitting device that emits green light. The subpixel 110B includes a light-emitting device that emits blue light. Thus, the display apparatus 10 can perform full-color display. Note that the pixel 150 may include a subpixel including a light-emitting device that emits light of another color. For example, the pixel 150 may include, in addition to the three subpixels, a subpixel including a light-emitting device that emits white light, a subpixel including a light-emitting device that emits yellow light, or the like.

The wiring GL is electrically connected to the subpixel 110R, the subpixel 110G, and the subpixel 110B arranged in a row direction (an extending direction of the wiring GL). The wiring SLR, the wiring SLG, and the wiring SLB are electrically connected to the subpixels 110R, the subpixels 110G, and the subpixels 110B (not illustrated) arranged in a column direction (an extending direction of the wiring SLR and the like), respectively.

### [Structure Example of Pixel Circuit]

FIG. 10B illustrates an example of a circuit diagram of the pixel 150 that can be used as the subpixel 110R, the subpixel 110G, and the subpixel 110B. The pixel 150 includes a transistor M1, a transistor M2, a transistor M3, a capacitor C1, and a light-emitting device EL. The wiring GL and a wiring SL are electrically connected to the pixel 150. The wiring SL corresponds to any of the wiring SLR, the wiring SLG, and the wiring SLB illustrated in FIG. 10A.

A gate of the transistor M1 is electrically connected to the wiring GL, one of a source and a drain of the transistor M1 is electrically connected to the wiring SL, and the other thereof is electrically connected to one electrode of the capacitor C1 and a gate of the transistor M2. One of a source and a drain of the transistor M2 is electrically connected to a wiring AL, and the other of the source and the drain thereof is electrically connected to one electrode of the light-emitting device EL, the other electrode of the capacitor C1, and one of a source and a drain of the transistor M3. A gate of the transistor M3 is electrically connected to the wiring GL, and the other of the source and the drain thereof is electrically connected to a wiring RL. The other electrode of the light-emitting device EL is electrically connected to a wiring CL.

A data potential D is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 150, the anode potential is a potential higher than the cathode potential. The reset potential supplied to the wiring RL can be set such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. The transistor M2 functions as a transistor for controlling current flowing through the light-emitting device EL. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In this case, an LTPS transistor can be used as at least one of a plurality of transistors included in the driver circuit portion 12 and a plurality of transistors included in the driver circuit portion 13, and OS transistors can be used as the other transistors. For example, OS transistors can be used as the transistors provided in the pixel portion 103, and LTPS transistors can be used as the transistors provided in the driver circuit portion 12 and the driver circuit portion 13.

As the OS transistor, a transistor including an oxide semiconductor in its semiconductor layer where a channel is formed can be used. The semiconductor layer preferably includes indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one or more kinds selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Further alternatively, it is preferable to use an oxide containing indium, gallium, tin, and zinc.

A transistor using an oxide semiconductor having a wider band gap and a lower carrier density than silicon can achieve an extremely low off-state current. Accordingly, such a low off-state current enables long-term retention of charge accumulated in a capacitor that is connected to the transistor in series. Thus, it is particularly preferable to use a transistor including an oxide semiconductor as the transistor M1 and the transistor M3 each of which is connected to the capacitor C1 in series. The use of the transistor including an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long time without rewriting data in the pixel 150.

Note that although the transistors are illustrated as n-channel transistors in FIG. 10B, a p-channel transistor can also be used.

The transistors included in the pixel 150 are preferably formed to be arranged over the same substrate.

Transistors each including a pair of gates overlapping with each other with a semiconductor layer therebetween can be used as the transistors included in the pixel 150.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 150 illustrated in FIG. 10C is an example in which a transistor including a pair of gates is used as the transistor M3. The gates of the transistor M3 are electrically connected to each other. Such a structure can shorten the period in which data is written to the pixel 150.

The pixel 150 illustrated in FIG. 10D is an example in which a transistor including a pair of gates is used also as each of the transistor M1 and the transistor M2 in addition to the transistor M3. In any of the transistors, the pair of gates are electrically connected to each other. When such a transistor is used at least as the transistor M2, the saturation characteristics are improved, whereby emission luminance of the light-emitting device EL can be controlled easily and the display quality can be increased.

The pixel 150 illustrated in FIG. 10E is an example in which one of the pair of gates of the transistor M2 in the pixel 150 illustrated in FIG. 10D is electrically connected to the source of the transistor M2.

### STRUCTURE EXAMPLE OF TRANSISTOR

Cross-sectional structure examples of a transistor that can be used in the above display apparatus are described below.

### Structure Example 1

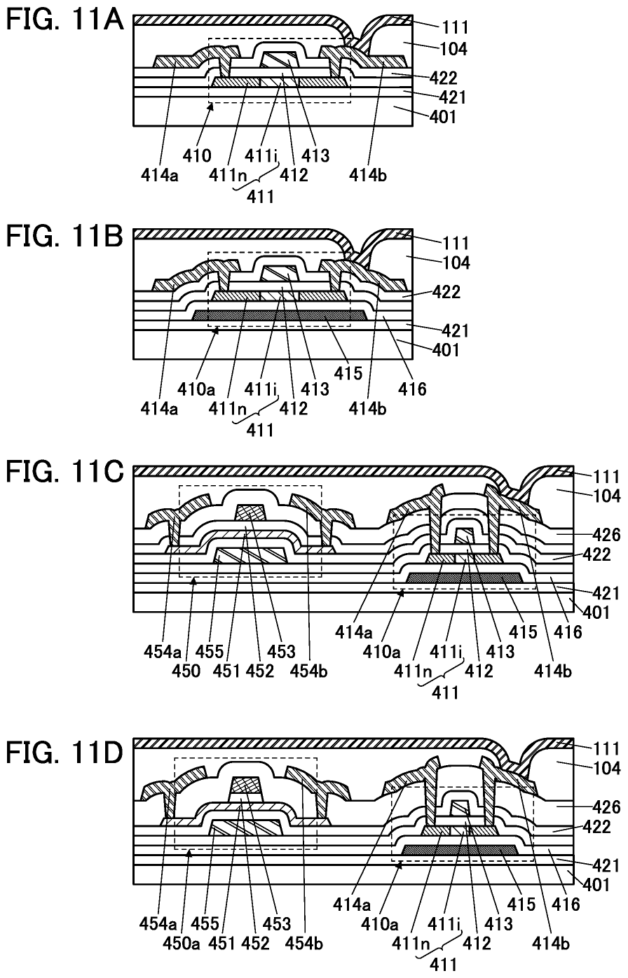

FIG. 11A is a cross-sectional view including a transistor 410.

The transistor 410 is provided over a substrate 401 and contains polycrystalline silicon in its semiconductor layer. For example, the transistor 410 corresponds to the transistor M2 in the pixel 150. In other words, FIG. 11A illustrates an example in which one of a source and a drain of the transistor 410 is electrically connected to the lower electrode 111 of the light-emitting device.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can include a metal oxide exhibiting semiconductor characteristics (also referred to as an oxide semiconductor). In this case, the transistor 410 can be referred to as an OS transistor.

The low-resistance regions 411n are each a region containing an impurity element. For example, in the case where the transistor 410 is an n-channel transistor, phosphorus, arsenic, or the like is added to the low-resistance regions 411n. Meanwhile, in the case where the transistor 410 is a p-channel transistor, boron, aluminum, or the like is added to the low-resistance regions 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are electrically connected to the low-resistance regions 411n in opening portions provided in the insulating layer 422 and the insulating layer 412. Part of the conductive layer 414a functions as one of a source electrode and a drain electrode, and part of the conductive layer 414b functions as the other of the source electrode and the drain electrode. An insulating layer 104 is provided to cover the conductive layer 414a, the conductive layer 414b, and the insulating layer 422.

The lower electrode 111 functioning as a pixel electrode is provided over the insulating layer 104. The lower electrode 111 is provided over the insulating layer 104 and is electrically connected to the conductive layer 414b in an opening provided in the insulating layer 104. Although not illustrated here, an EL layer and a common electrode can be stacked over the lower electrode 111.

### Structure Example 2

FIG. 11B illustrates a transistor 410a including a pair of gate electrodes. The transistor 410a illustrated in FIG. 11B is different from that in FIG. 11A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 11B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case of using LTPS transistors as all of the transistors included in the pixel 150, the transistor 410 illustrated in FIG. 11A as an example or the transistor 410a illustrated in FIG. 11B as an example can be used. In this case, the transistors 410a may be used as all of the transistors included in the pixels 150, the transistors 410 may be used as all of the transistors, or the transistors 410a and the transistors 410 may be used in combination.

### Structure Example 3

Described below is an example of a structure including both a transistor containing silicon in its semiconductor layer and a transistor containing a metal oxide in its semiconductor layer.

FIG. 11C is a cross-sectional view including the transistor 410a and a transistor 450.

Structure example 1 described above can be referred to for the transistor 410a. Although an example using the transistor 410a is illustrated here, a structure including the transistor 410 and the transistor 450 or a structure including all the transistor 410, the transistor 410a, and the transistor 450 may alternatively be employed.

The transistor 450 is a transistor including metal oxide in its semiconductor layer. The structure in FIG. 11C illustrates an example in which the transistor 450 and the transistor 410a respectively correspond to the transistor M1 and the transistor M2 in the pixel 150. That is, FIG. 11C illustrates an example in which one of a source and a drain of the transistor 410a is electrically connected to the lower electrode 111.

Moreover, FIG. 11C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in opening portions provided in the insulating layer 426 and the insulating layer 452. Part of the conductive layer 454a functions as one of a source electrode and a drain electrode, and part of the conductive layer 454b functions as the other of the source electrode and the drain electrode. The insulating layer 104 is provided to cover the conductive layer 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b. In FIG. 11C, the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This is preferable because the manufacturing process can be simplified.

Moreover, the conductive layer 413 functioning as the first gate electrode of the transistor 410a and the conductive layer 455 functioning as the second gate electrode of the transistor 450 are preferably formed by processing the same conductive film. FIG. 11C illustrates a structure where the conductive layer 413 and the conductive layer 455 are formed on the same plane (i.e., in contact with the top surface of the insulating layer 412) and contain the same metal element. This is preferable because the manufacturing process can be simplified.

In the structure in FIG. 11C, the insulating layer 452 functioning as the first gate insulating layer of the transistor 450 covers an end portion of the semiconductor layer 451; however, the insulating layer 452 may be processed to have the same or substantially the same top surface shape as the conductive layer 453 as in the transistor 450a illustrated in FIG. 11D.

Note that in this specification and the like, the expression “top surface shapes are substantially the same” means that at least outlines of stacked layers partly overlap with each other. For example, the case of processing an upper layer and a lower layer with the use of the same mask pattern or mask patterns that are partly the same is included. However, in some cases, the outlines do not completely overlap with each other and the upper layer is positioned inward from the lower layer or the upper layer is positioned outward from the lower layer; such cases are also represented by the expression “top surface shapes are substantially the same”.

Although the example in which the transistor 410a corresponds to the transistor M2 and is electrically connected to the pixel electrode is shown here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

By including the above pixel circuit and having the structure of the light-emitting device described in the above embodiment, the display apparatus can display an image with any one or more of image crispness, image sharpness, high chroma, and a high contrast ratio. The display apparatus is preferable; the leakage current that might flow through the transistors in the pixel circuit is extremely low, and the lateral leakage current between the light-emitting devices in the above embodiment is extremely low, leading to little leakage of light or the like at the time of black display.

This embodiment can be combined with the other embodiments as appropriate. In the case where a plurality of structure examples are described in one embodiment in this specification, the structure examples can be combined as appropriate.

### Embodiment 6

In this embodiment, a display apparatus including a light-receiving device (also referred to as a light-receiving element) will be described.

The pixel portion may include a light-receiving device, in which case a display apparatus having a light-receiving function can be provided. The display apparatus having alight-receiving function can detect a touch or approach of an object while an image is displayed. A region where the light-receiving device is positioned is referred to as a light-receiving portion, and the light-receiving portion also includes a switching element that controls the light-receiving device. The light-receiving device controlled by the switching element has a function of receiving light from a light source and can convert received light into an electric signal.

Furthermore, an image may be displayed by using all the subpixels included in the display apparatus; alternatively, light may be emitted by some of the subpixels as the light source and an image may be displayed by using the rest of the subpixels.

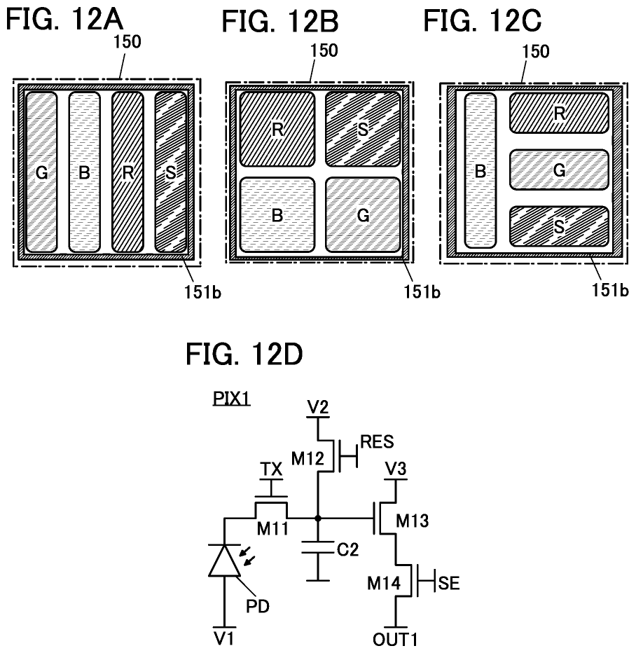

The pixels 150 illustrated in FIG. 12A, FIG. 12B, and FIG. 12C each include the subpixel 110G, the subpixel 110B, the subpixel 110R, and a light-receiving portion S (denoted as R, G, B, and S in the drawing) and further includes the auxiliary wiring. FIG. 12A, FIG. 12B, and FIG. 12C illustrate the second wiring layer 15b that is part of the auxiliary wiring 151. In FIG. 12A, FIG. 12B, and FIG. 12C, regions are denoted by R, G, B, and S to easily differentiate the subpixels or the like.

In the pixel 150 illustrated in FIG. 12A, stripe arrangement is employed, and the second wiring layer 151b is provided so as to surround the subpixel 110G, the subpixel 110B, the subpixel 110R, and the light-receiving portion S (denoted as R, G, B, and S in the drawing).

The pixel illustrated in FIG. 12B employs matrix arrangement, and the second wiring layer 151b is provided so as to surround the subpixel 110G, the subpixel 110B, the subpixel 110R, and the light-receiving portion S.

In the pixel 150 illustrated in FIG. 12C, arrangement in which three subpixels (the subpixel 110R, the subpixel 110G, and the light-receiving portion S) are aligned vertically next to one subpixel (the subpixel 110B) is employed, and the second wiring layer 151b is provided so as to surround the subpixel 110G, the subpixel 110B, the subpixel 110R, and the light-receiving portion S.

Note that the layout of the subpixels is not limited to the structures illustrated in FIG. 12A to FIG. 12C. The layout of the second wiring layer 151b is not limited to the structure illustrated in FIG. 12A to FIG. 12C.

In the case where a light-receiving area of the light-receiving portion S is smaller than a light-emitting area of each of the other subpixels, image-capturing range becomes narrow, which can inhibit a blur in a captured result and increase definition. Thus, the display apparatus of one embodiment of the present invention can perform high-resolution or high-definition image capturing. For example, image capturing for personal authentication with the use of a fingerprint, a palm print, the iris, the shape of a blood vessel (including the shape of a vein and the shape of an artery), a face, or the like is possible by using the light-receiving portion S.

Moreover, the light-receiving portion S can be used in a touch sensor (also referred to as a direct touch sensor), a near touch sensor (also referred to as a hover sensor, a hover touch sensor, a contactless sensor, or a touchless sensor), or the like.

A touch sensor or a near touch sensor can sense an approach or contact of an object (a finger, a hand, a pen, or the like). The touch sensor can sense the object when the display apparatus and the object come in direct contact with each other. Furthermore, even when an object is not in contact with the display apparatus, the near touch sensor can sense the object. For example, the display apparatus is preferably capable of sensing an object positioned in the range of 0.1 mm to 300 mm inclusive, further preferably 3 mm to 50 mm inclusive from the display apparatus. This structure enables the display apparatus to be operated without direct contact of an object, that is, enables the display apparatus to be operated in a contactless (touchless) manner. With the above-described structure, the display apparatus can have a reduced risk of being dirty or damaged, or can be operated without the object directly touching a dirt (e.g., dust or a virus) attached to the display apparatus.

For high-resolution image capturing, the light-receiving portion S is preferably provided in all pixels included in the display apparatus. Meanwhile, in the case where the light-receiving portion S is used in a touch sensor or a near touch sensor, high accuracy is not required as compared to the case of capturing an image of a fingerprint; accordingly, the light-receiving portion S only needs to be provided in some of the pixels in the display apparatus. When the number of the light-receiving portions S included in the display apparatus is smaller than the number of the subpixels 110R or the like, higher sensing speed can be achieved.

FIG. 12D illustrates an example of a pixel circuit of a subpixel (PIX1) including a light-receiving device.

A pixel circuit illustrated in FIG. 12D includes a light-receiving device PD, a transistor M11, a transistor M12, a transistor M13, a transistor M14, and a capacitor C2. Here, a photodiode is used as an example of the light-receiving device PD.

An anode of the light-receiving device PD is electrically connected to a wiring V1 and a cathode of the light-receiving device PD is electrically connected to one of a source and a drain of the transistor M11. A gate of the transistor M11 is electrically connected to a wiring TX, and the other of the source and the drain thereof is electrically connected to one electrode of the capacitor C2, one of a source and a drain of the transistor M12, and a gate of the transistor M13. A gate of the transistor M12 is electrically connected to a wiring RES, and the other of the source and the drain thereof is electrically connected to a wiring V2. One of a source and a drain of the transistor M13 is electrically connected to a wiring V3, and the other of the source and the drain thereof is electrically connected to one of a source and a drain of the transistor M14. Agate of the transistor M14 is electrically connected to a wiring SE, and the other of the source and the drain thereof is electrically connected to a wiring OUT1.

A constant potential is supplied to the wiring V1, the wiring V2, and the wiring V3. To drive the light-receiving device PD, the wiring V2 is supplied with a potential higher than the potential of the wiring V1. The transistor M12 is controlled by a signal supplied to the wiring RES and has a function of resetting the potential of a node connected to the gate of the transistor M13 to a potential supplied to the wiring V2. The transistor M11 is controlled by a signal supplied to the wiring TX and has a function of controlling the timing at which the potential of the node changes, in accordance with a current flowing through the light-receiving device PD. The transistor M13 functions as an amplifier transistor for performing output corresponding to the potential of the node. The transistor M14 is controlled by a signal supplied to the wiring SE and functions as a selection transistor for making an external circuit electrically connected to the wiring OUT1 read the output corresponding to the potential of the node.

A transistor using a metal oxide (an oxide semiconductor) in its semiconductor layer where a channel is formed (an OS transistor) is preferably used as each of the transistor M11, the transistor M12, the transistor M13, and the transistor M14.

An OS transistor having a wider band gap and a lower carrier density than silicon can achieve an extremely low off-state current.

Alternatively, a transistor including silicon as a semiconductor where a channel is formed can be used as each of the transistor M11 to the transistor M14. It is particularly preferable to use silicon with high crystallinity, such as single crystal silicon or polycrystalline silicon, because high field-effect mobility can be achieved and higher-speed operation can be performed.

Alternatively, a transistor using an oxide semiconductor may be used as one or more of the transistor M11 to the transistor M14, and transistors using silicon may be used as the other transistors.

Although n-channel transistors are shown as the transistors in FIG. 12D, p-channel transistors can be used.

The refresh rate of the display apparatus of one embodiment of the present invention can be variable. For example, the refresh rate is adjusted (in the range from 0.01 Hz to 240 Hz inclusive, for example) in accordance with contents displayed on the display apparatus, whereby power consumption can be reduced. Moreover, driving with a lowered refresh rate that reduces the power consumption of the display apparatus may be referred to as idling stop (IDS) driving.

The driving frequency of the touch sensor or the near touch sensor may be changed in accordance with the refresh rate. For example, when the refresh rate of the display apparatus is 120 Hz, the driving frequency of the touch sensor or the near touch sensor can be higher than 120 Hz (can typically be 240 Hz). With this structure, low power consumption can be achieved, and the response speed of the touch sensor or the near touch sensor can be increased.

This embodiment can be combined with the other embodiments as appropriate. In the case where a plurality of structure examples are described in one embodiment in this specification, the structure examples can be combined as appropriate.

### Embodiment 7

In this embodiment, a metal oxide (also referred to as an oxide semiconductor) that can be used in the OS transistor described in the above embodiment will be described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a CVD method such as an MOCVD method, an ALD method, or the like.

### <Classification of Crystal Structure>

Amorphous (including completely amorphous), CAAC (c-axis-aligned crystalline), nc (nanocrystalline), CAC (cloud-aligned composite), single-crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method.

For example, the XRD spectrum of the quartz glass substrate shows a peak with a substantially bilaterally symmetrical shape. On the other hand, the peak of the XRD spectrum of the IGZO film having a crystal structure has a bilaterally asymmetrical shape. The bilaterally asymmetrical peak of the XRD spectrum clearly shows the existence of crystals in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film formed at room temperature. Thus, it is suggested that the IGZO film formed at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a plurality of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Thus, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Thus, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in a nanobeam electron diffraction pattern of the nc-OS film obtained using an electron beam with a probe diameter nearly equal to or smaller than the diameter of a nanocrystal (e.g., 1 nm or larger and 30 nm or smaller).

[a-Like OS]

The a-like OS is an oxide semiconductor having a structure between those of the nc-OS and the amorphous oxide semiconductor. The a-like OS contains a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. For example, the first region has higher [In] and lower [Ga] than the second region. Moreover, the second region has higher [Ga] and lower [In] than the first region.

Specifically, the first region contains an indium oxide, an indium zinc oxide, or the like as its main component. The second region contains a gallium oxide, a gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and less than 30%, further preferably higher than or equal to 0% and less than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

A transistor using the CAC-OS has high reliability. Thus, the CAC-OS is most suitable for a variety of semiconductor devices such as display apparatuses.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

This embodiment can be combined with the other embodiments as appropriate. In the case where a plurality of structure examples are described in one embodiment in this specification, the structure examples can be combined as appropriate.

### Embodiment 8

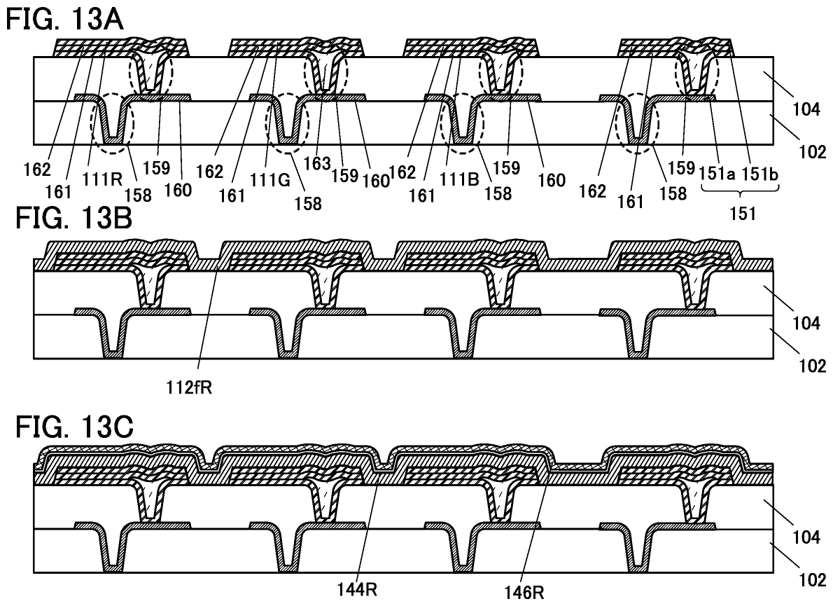

An example of a method for manufacturing the above-described display apparatus will be described with reference to FIG. 13 to FIG. 17 and the like. In the drawings, a region related to the pixel 150 is illustrated on the left side, and a region on the auxiliary wiring 151 is illustrated on the right side.

### Manufacturing Method Example 1

Note that thin films included in the display apparatus (insulating films, semiconductor films, conductive films, and the like) can be formed by a sputtering method, a CVD method, a vacuum evaporation method, a PLD method, an ALD method, or the like. Examples of the CVD method include a plasma-enhanced chemical vapor deposition (PECVD) method, a thermal CVD method, and the like. An example of a thermal CVD method is a metal organic chemical vapor deposition (MOCVD: Metal Organic CVD) method.

Thin films included in the display apparatus (insulating films, semiconductor films, conductive films, resin films, and the like) can be formed by a method such as spin coating, dipping, spray coating, ink-jetting, dispensing, screen printing, offset printing, a doctor knife method, slit coating, roll coating, curtain coating, or knife coating. These are wet deposition methods.

The thin films included in the display apparatus can be processed by a photolithography method or the like. Besides, the thin films may be processed by a nanoimprinting method, a sandblasting method, a lift-off method, or the like. Furthermore, the thin films may be directly formed by a deposition method using a metal mask, or the like.

There are typically the following two photolithography methods. In one of the methods, a resist mask is formed over a thin film that is to be processed, the thin film is processed by etching or the like, and then the resist mask is removed. In the other method, a photosensitive thin film is deposited and then processed into a desired shape by light exposure and development.

For light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. Alternatively, for the light used for the light exposure, extreme ultraviolet (EUV) light, X-rays, or the like may be used. Furthermore, instead of the light used for the light exposure, an electron beam can also be used. Extreme ultraviolet light, X-rays, or an electron beam is preferably used, in which case extremely minute processing can be performed. Note that when light exposure is performed by scanning of abeam such as an electron beam, a resist mask is not needed.

For etching of the thin films, a dry etching method, a wet etching method, a sandblasting method, or the like can be used.

### [Preparation of Substrate]

Although not illustrated, a substrate is prepared. As the substrate, a substrate having at least heat resistance high enough to withstand heat treatment performed later can be used. In the case where an insulating substrate is used as the substrate, a glass substrate, a quartz substrate, a sapphire substrate, a ceramic substrate, an organic resin substrate, or the like can be used. Alternatively, it is possible to use a semiconductor substrate such as a single crystal semiconductor substrate or a polycrystalline semiconductor substrate including silicon, silicon carbide, or the like as a material; a compound semiconductor substrate of silicon germanium or the like; or an SOI substrate.

As the substrate, it is preferable to prepare the semiconductor substrate or the insulating substrate where a pixel circuit including a semiconductor element such as a transistor is formed. A substrate in which a gate line driver circuit (a gate driver), a source line driver circuit (a source driver), or the like is formed besides the pixel circuit, may be used. In addition to the above, a substrate where an arithmetic circuit, a memory circuit, or the like is formed may be used.

### [Formation of Insulating Layer 102]

As illustrated in FIG. 13A, an insulating layer 102 is formed over the above substrate. For the insulating layer 102, an inorganic material or an organic material can be used. The organic material is preferable because it enables the insulating layer 104 to surely have a planar top surface. As the organic material, one or two or more selected from an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used. In the case where two or more of the organic materials are used, the selected organic materials are stacked.

As illustrated in FIG. 13A, the insulating layer 102 includes a contact hole 158. The contact hole 158 can be formed by a photolithography method, for example.

[Formation of Conductive Layer 160 and First Wiring Layer 151a]

As illustrated in FIG. 13A, a conductive layer 160 and the first wiring layer 151a are formed over the insulating layer 102 and in the contact hole 158. That is, the conductive layer 160 and the first wiring layer 151a are formed on the same formation surface through the same process. Specifically, a conductive film formed over the insulating layer 102 and in the contact hole 158 is processed to obtain the conductive layer 160 and the first wiring layer 151a.

The conductive layer 160 is electrically connected to the transistor of the pixel circuit and is also electrically connected to the lower electrode 111. The conductive layer 160 can be processed to have an elongated shape over the insulating layer 102 and can function as a signal line, a power supply line, a scan line, or the like. Furthermore, the conductive layer 160 may be a conductive layer not for functioning as a wire but for electrically connecting the transistor and the lower electrode 111 to each other. The first wiring layer 151a can function as a lower wiring layer of the auxiliary wiring 151 and is processed to have an elongated shape, a lattice shape, or the like over the insulating layer 102. The first wiring layer 151a does not affect an aperture ratio and accordingly may have a shape with a large area. Note that the first wiring layer 151a is not in contact with the conductive layer 160.

For the conductive layer 160 and the first wiring layer 151a, one or more metal materials selected from aluminum, titanium, chromium, manganese, iron, cobalt, nickel, copper, gallium, zinc, indium, tin, molybdenum, tantalum, tungsten, palladium, gold, platinum, silver, yttrium, neodymium, and the like, an alloy containing an appropriate combination of any of these, or the like can be used. Since the first wiring layer 151a functions as a lower wiring layer of the auxiliary wiring, a metal material having low resistivity is preferably used.

The conductive layer 160 and the first wiring layer 151a may each have a single-layer structure containing the above metal material or a stacked-layer structure containing the above metal material.

### [Formation of Insulating Layer 104]

As illustrated in FIG. 13A, the insulating layer 104 is formed over the insulating layer 102. For the insulating layer 104, an inorganic material or an organic material can be used. The organic material is preferable because it enables the insulating layer 104 to surely have a planar top surface. As the organic material, one or two or more selected from an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used. In the case where two or more of the organic materials are used, the selected organic materials are stacked.

The insulating layer 104 includes a contact hole 159. The contact hole 159 can be formed by a photolithography method or the like, and part of the conductive layer 160 is exposed in the contact hole 159. The contact hole 159 does not overlap with the contact hole 158 and is preferably provided at a position overlapping with the conductive layer 160 provided over the flat top surface of the insulating layer 102. In the case where the contact hole 159 overlaps with the contact hole 158, the contact hole 159 is preferably larger than the contact hole 158.

### [Formation of Conductive Layer 161, Resin Layer 163, and Conductive Layer 162]

As illustrated in FIG. 13A, in the contact hole 159, a conductive layer 161 is formed followed by formation of a resin layer 163, and then a conductive layer 162 is formed. The lower electrode 111 and the second wiring layer 151b may be formed without formation of the conductive layer 161, the resin layer 163, and the conductive layer 162.

A conductive film to be the conductive layer 161 is deposited over the insulating layer 104 and the contact hole 159. Preferably, the top surface of the insulating layer 104 is a formation surface of the conductive film and has planarity to make the conductive film less likely to be cut. For the conductive layer 161, it is possible to use one or two or more metal materials selected from aluminum, titanium, chromium, manganese, iron, cobalt, nickel, copper, gallium, zinc, indium, tin, molybdenum, tantalum, tungsten, palladium, gold, platinum, silver, yttrium, neodymium, and the like, an alloy containing an appropriate combination of any of these, or the like.

In the case where the surface of the conductive film has a depressed portion after being formed, a layer containing a resin (also referred to as a resin layer) 163 is preferably formed as an organic material in the depressed portion. With the resin layer 163, unevenness due to the insulating layer 104, the contact hole 159, and the conductive layer 161 can be reduced.

It is preferable to use a photosensitive resin for the resin layer 163. At this time, the resin layer 163 can be formed in the following manner: a resin film is deposited first, then is exposed to light through a resist mask, and finally is subjected to development treatment. Further preferably, in order to adjust the level of the top surface of the resin layer 163, an upper portion of the resin layer 163 may be etched by ashing or the like.

In the case where a non-photosensitive resin is used for the resin layer 163, the resin layer 163 can be formed in the following manner: a resin film is deposited, and then an upper portion of the resin film is etched by ashing or the like. The ashing is performed until the surface of the conductive film to be the conductive layer 161 is exposed. The thickness of the resin layer 163 can be optimized by ashing or the like.

Next, a conductive film to be the conductive layer 162 is deposited over the resin layer 163. The conductive layer 162 preferably contains one or two or more selected from the metals and the like described for the conductive layer 161.

[Formation of Lower Electrode 111 and Second Wiring Layer 151b]

As illustrated in FIG. 13A, a conductive film to be the lower electrode 111 and the second wiring layer 151b is formed to cover the conductive film to be the conductive layer 161 and the conductive film to be the conductive layer 162. The lower electrode 111 has a function of an anode or a cathode, and a metal, an alloy, an electrically conductive compound, a mixture thereof, or the like can be used as appropriate. Specific materials usable for the lower electrode 111 can be referred to for the description of the lower electrode. The second wiring layer 151b is preferably formed using the same material as the lower electrode 111.

After that, a resist mask is formed over the three conductive films by a photolithography method, and unnecessary portions of the conductive films are removed by etching. Then, the resist mask is removed, whereby the conductive layer 161, the conductive layer 162, the lower electrode 111, and the second wiring layer 151b can be formed using the same resist mask in the same etching step. The lower electrode 111 and the second wiring layer 151b can each have a flat top surface with the resin layer 163 or the like.

Note that although the conductive layer 161 and the conductive layer 162 are formed using the same resist mask in the same etching step here, the conductive layer 161 and the conductive layer 162 may be separately processed using different resist masks. In this case, the conductive layer 161 and the conductive layer 162 are preferably processed so that the conductive layer 162 is encircled by the outline of the conductive layer 161 in a top view.

Although the conductive layer 162, the lower electrode 111, and the like are formed using the same resist mask in the same etching step, the conductive layer 162, the lower electrode 111, and the like may be separately processed using different resist masks. In this case, the conductive layer 162, the lower electrode 111, and the like are preferably processed so that the lower electrode 111 is encircled by the outline of the conductive layer 162 and the like in a top view.

[Deposition of Organic Compound Film 112fR]

As illustrated in FIG. 13B, an organic compound film 112fR capable of emitting red light is deposited to cover the lower electrode 111 and the second wiring layer 151b. The organic compound film 112fR has a structure in which the functional layers of the light-emitting device are stacked. Although the organic compound film capable of emitting red light is deposited first, an organic compound capable of emitting green light may be deposited first in one embodiment of the present invention. Furthermore, in one embodiment of the present invention, an organic compound capable of emitting blue light may be deposited first.

The organic compound film 112fR may have a single structure or a tandem structure. In the case where the organic compound film 112fR has a tandem structure, a charge-generation layer is preferably provided between a first light-emitting unit and a second light-emitting unit.

For the charge-generation layer, a layer containing a hole-transport material and an acceptor material (electron-accepting material) can be used. For the charge-generation layer, a layer containing an electron-transport material and a donor material can be used.

The above-described material for the electron-injection layer may be used as the electron-transport material. Since the charge-generation layer is processed by etching or the like later, a material that does not contain an alkali metal or an alkaline earth metal among the materials used for the electron-injection layer is preferably used; for example, an organic compound containing a dopant is preferably used. NBPhen can be used as the organic compound, and Ag can be used as a dopant.

The functional layer included in the organic compound film 112fR can be deposited by a vacuum evaporation method. Without limitation to this, the functional layer included in the organic compound film 112fR can be deposited also by a sputtering method, an inkjet method, or the like.

Although the organic compound film 112fR is formed to cover the second wiring layer 151b in FIG. 13B, the second wiring layer 151b is not necessarily covered. This can preferably prevents the second wiring layer 151b from being in contact with the organic compound film 112fR, whereby the removal agent at the time of removing the organic compound film 112fR does not reach the surfaces of the lower electrode 111 and the second wiring layer 151b.

The organic compound film 112fR may be deposited separately using a fine metal mask. In this case, the organic compound film 112fR is preferably formed so as to cover only the lower electrode 111R. This preferably prevents the second wiring layer 151b from being in contact with the organic compound film 112fR, whereby the removal agent at the time of removing the organic compound film 112fR does not reach the surfaces of the lower electrode 111 and the second wiring layer 151b.

The organic compound film 112fR includes functional layers and is preferably a stack including at least a hole-injection layer, a hole-transport layer, a light-emitting layer, and an electron-transport layer in order from the lower electrode 111 side, for example.

Note that an electron-injection layer positioned over the electron-transport layer is one of the functional layers. In this embodiment, the electron-injection layer is formed later to be the common layer. The common layer may be any layer as long as it is a functional layer positioned between the light-emitting layer and the common electrode. Needless to say, all the functional layers may be divided for each subpixel without providing the common layer.

The electron-transport layer positioned in the uppermost layer of the organic compound film 112fR is exposed to a processing process using a photolithography method. Thus, a material having high heat resistance is preferably used for the electron-transport layer. As the material having high heat resistance, a material whose glass transition point is higher than or equal to 110° C. and lower than or equal to 165° C., and preferably higher than or equal to 120° C. and lower than or equal to 135° C. is preferably used, for example.

The electron-transport layer exposed to the processing may have a stacked-layer structure. An example of the stacked-layer structure is a structure in which a second electron-transport layer is stacked over a first electron-transport layer. The processing includes a period in which the first electron-transport layer is covered with the second electron-transport layer is provided; accordingly, the first electron-transport layer may have lower heat resistance than the second electron-transport layer. For example, a material with a glass transition point higher than or equal to 110° C. and lower than or equal to 165° C., preferably higher than or equal to 120° C. and lower than or equal to 135° C. can be used for the second electron-transport layer, and a material with a glass transition point lower than that of the second electron-transport layer, for example, higher than or equal to 100° C. and lower than or equal to 155° C., preferably higher than or equal to 110° C. and lower than or equal to 125° C. can be used for the first electron-transport layer.

It can be considered to make the uppermost layer of the organic compound film 112fR the light-emitting layer; however, damage to the light-emitting layer caused by the processing might significantly degrade the reliability. Thus, in the manufacturing of the display apparatus of one embodiment of the present invention, the processing is preferably performed after the functional layer (e.g., an electron-transport layer) is formed above the light-emitting layer.

### [Deposition of Mask Film 144R]

Furthermore, a mask layer or the like is preferably formed over the organic compound film. The mask layer can inhibit the processing from damaging the light-emitting layer. This method can provide a highly reliable display panel. Note that in this specification and the like, the mask layer is positioned above the organic compound film and has a function of protecting the organic compound film in the manufacturing process. Thus, as illustrated in FIG. 13C, a mask film 144R is deposited to cover the organic compound film 112f.

As the mask film 144R, a film having high etching selectivity with respect to the organic compound film 112fR is preferably used during the etching treatment of the organic compound film 112fR. In addition, the mask film 144R is in a stacked-layer structure in some cases; a film having high etching selectivity with respect to the mask film (specifically, a mask film 146R) or the like in the upper layer described later is preferably used as the mask film 144R. Furthermore, at the time of removing the mask film 144R, it is preferable to use a film that can be removed by a wet etching method that is less likely to cause damage to the organic compound film 112fR.

As the mask film 144R, an inorganic film such as a metal film, an alloy film, a metal oxide film, a semiconductor film, or an inorganic insulating film can be suitably used, for example. The mask film 144R can be formed by any of a variety of deposition methods such as a sputtering method, an evaporation method, a CVD method, and an ALD method.

Specifically, the mask film 144R, which is directly formed on the organic film 112fR, is preferably formed by an ALD method that gives less deposition damage to a formation layer.

For the mask film 144R, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

Alternatively, the mask film 144R can be formed using a metal oxide such as an indium-gallium-zinc oxide (also referred to as an In—Ga—Zn oxide or IGZO). It is also possible to use an indium oxide, an indium zinc oxide (an In—Zn oxide), an indium tin oxide (an In—Sn oxide), an indium titanium oxide (an In—Ti oxide), an indium tin zinc oxide (an In—Sn—Zn oxide), an indium titanium zinc oxide (an In—Ti—Zn oxide), an indium gallium tin zinc oxide (an In—Ga—Sn—Zn oxide), or the like. Alternatively, an indium tin oxide containing silicon, or the like can also be used.

Note that an element M (M is one or more selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) can be employed instead of gallium. Specifically, M is preferably one or more kinds selected from gallium, aluminum, and yttrium.

The mask film 144R may contain an inorganic material. As the inorganic material, an oxide such as aluminum oxide, hafnium oxide, or silicon oxide, a nitride such as silicon nitride or aluminum nitride, or an oxynitride such as silicon oxynitride can be used. Such an inorganic material can be formed by a deposition method such as a sputtering method, a CVD method, or an ALD method.

The mask film 144R may contain an organic material. For example, as the organic material, a material that can be dissolved in a solvent chemically stable with respect to the organic film 112fR may be used. In particular, a material that is dissolved in water or alcohol can be suitably used for the mask film 144R. In deposition of the mask film 144R, it is preferable that application of such a material that has been dissolved in a solvent such as water or alcohol be performed by a wet deposition method followed by heat treatment for evaporating the solvent. At this time, the heat treatment is preferably performed in a reduced-pressure atmosphere, in which case the solvent can be removed at a low temperature in a short time and thermal damage to the EL layer can be reduced accordingly.

A wet deposition method can be used to form the mask film 144R.

For the mask film 144R, an organic resin such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used. For the mask film 144R, a fluorine resin such as a perfluoropolymer may be used.

### [Deposition of Mask Film 146R]

As illustrated in FIG. 13C, the mask film 146R is deposited over the mask film 144R. Although a stacked-layer structure of mask films is employed in this embodiment; the organic compound film 112fR can be protected using only the mask film 144R or the mask film 146R as a single mask film.

The mask film 146R is preferably used as a hard mask when the mask film 144R is etched later. After the mask film 146R is processed, the mask film 144R is exposed. Thus, in the case where the mask film 146R is used as a hard mask, the combination of films having high etching selectivity therebetween is selected for the mask film 144R and the mask film 146R.

A material of the mask film 146R can be selected from a variety of materials depending on an etching condition of the mask film 144R and an etching condition of the mask film 146R. For example, any of the films usable for the mask film 144R can be selected, and different materials can be selected for the mask film 144R.

For example, an oxide film or an oxynitride film can be used as the mask film 146R. Typical examples of the oxide film and the oxynitride film include silicon oxide, silicon oxynitride, aluminum oxide, aluminum oxynitride, hafnium oxide, and hafnium oxynitride.

As the mask film 146R, a nitride film can be used, for example. Typical examples of the nitride film include silicon nitride, aluminum nitride, hafnium nitride, titanium nitride, tantalum nitride, tungsten nitride, gallium nitride, or germanium nitride.

For the combination of the mask film 144R and the mask film 146R, for example, it is possible that an inorganic material such as aluminum oxide, hafnium oxide, or silicon oxide formed by an ALD method and a metal oxide containing indium such as indium gallium zinc oxide (also referred to as an In—Ga—Zn oxide or IGZO) formed by a sputtering method are used for the mask film 144R and the mask film 146R, respectively.

Alternatively, for the mask film 146R combined with the mask film 144R, one or more metal selected from tungsten, molybdenum, copper, aluminum, titanium, tantalum, and the like or an alloy containing the metal can be used. In the case where the mask film 146R is formed as a hard mask, the above metal or alloy is preferably used. In the case where the mask film 146R is formed as a hard mask, the thickness of the mask film 146R is preferably larger than that of the mask film 144R.

### [Formation of Resist Mask 143]

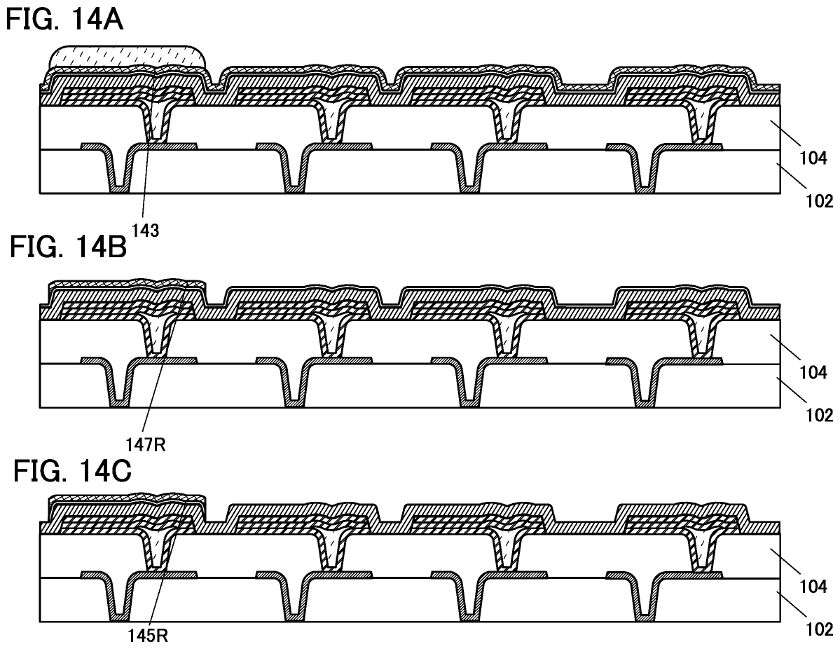

As illustrated in FIG. 14A, a resist mask 143 is formed in a position which is over the mask film 146R and overlaps with the lower electrode 111R. At this time, a resist mask is not formed in positions overlapping with the lower electrode 111G, the lower electrode 111B, and the auxiliary wiring 151.

For the resist mask 143, a resist material containing a photosensitive resin, such as a positive type resist material or a negative type resist material can be used.

The organic compound film 112fR or the like might be dissolved in the case where a material that dissolves the organic compound film 112fR is used fora solvent of the resist material, the mask film 146R is not provided, and defects such as pinholes exist in the mask film 144R. In this case, the mask film 146R can be positioned over the mask film 144R at the time of formation of the resist mask 143 to prevent such defects.

Note that in the case where a material that does not dissolve the organic compound film 112fR is used for the solvent of the resist material, the resist mask 143 may be formed directly on the mask film 144R without providing the mask film 146R.

### [Etching of Mask Film 146R]

As illustrated in FIG. 14B, part of the mask film 146R that is not covered with the resist mask 143 is removed by etching, so that a mask layer 147R is formed.

In the etching of the mask film 146R, an etching condition with high selectivity is preferably employed so that the mask film 144R is not removed by the etching. The etching of the mask film 146R can be performed by wet etching or dry etching.

### [Removal of Resist Mask 143]

The resist mask 143 is removed as illustrated in FIG. 14B. The resist mask 143 is removed in a state where the organic compound film 112fR is covered with the mask film 144R.

The resist mask 143 can be removed by wet etching or dry etching. It is particularly preferable to perform dry etching (also referred to as plasma ashing) using an oxygen gas as an etching gas to remove the resist mask 143.

As described above, the resist mask 143 is removed in a state where the organic compound film 112fR is covered with the mask film 144R; thus, damage to the organic compound film 112fR caused by the processing is inhibited. In particular, when the organic compound film 112fR is exposed to oxygen, the characteristics thereof might be adversely affected; accordingly, the organic compound film 112fR is preferably covered with the mask film 144R in the case where etching using the above oxygen gas is performed. Even in the case where the resist mask 143 is removed by wet etching, the organic film 112fR can be prevented from being dissolved because the organic film 112fR is not exposed to a chemical solution.

### [Etching of Mask Film 144R]

As illustrated in FIG. 14C, part of the mask film 144R is removed by etching using the mask layer 147R as a hard mask, so that a mask layer 145R is formed.

The etching of the mask film 144R can be performed by wet etching or dry etching.

[Etching of Organic Compound Film 112fR]

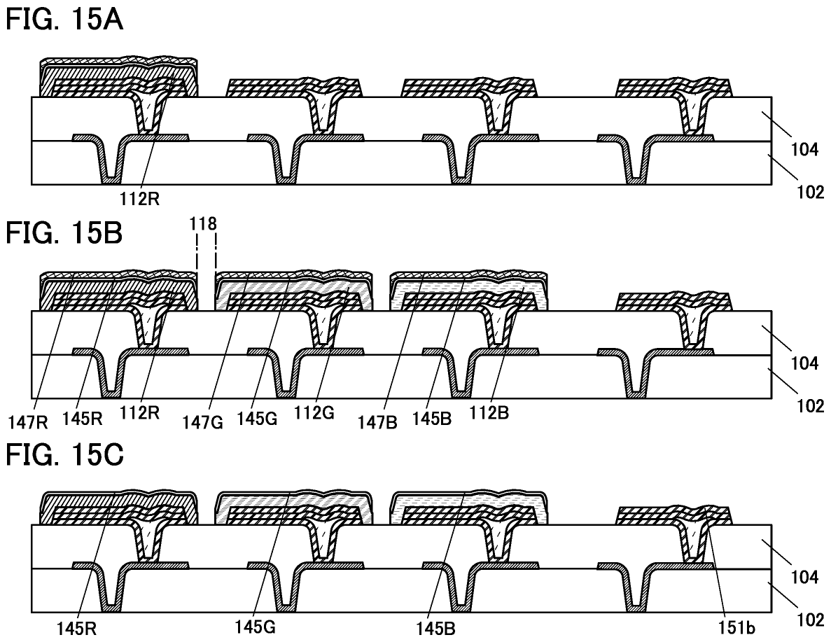

As illustrated in FIG. 15A, part of the organic compound film 112fR that is not covered with the mask layer 145R is removed by etching, whereby the organic compound layer 112R is formed. The organic compound layer 112R is an organic compound layer of the light-emitting device that emits red light.

For the etching of the organic film 112fR, it is preferable to perform dry etching using an etching gas that does not contain oxygen as its main component. This is because, as described above, the exposure of the organic compound film 112fR to oxygen adversely affects characteristics in some cases. Specifically, the organic compound film 112fR may be changed in quality; however, using an etching gas that does not contain oxygen as its main component can inhibit the change, whereby a highly reliable display apparatus can be achieved. Examples of the etching gas that does not contain oxygen as its main component include CF₄, C₄F₈, SF₆, CHF₃, Cl₂, H₂O, BCl₃, H₂, or a rare gas such as He. Alternatively, a mixed gas of the above gas and a dilution gas that does not contain oxygen can be used as the etching gas.

Note that etching of the organic film 112fR is not limited to the above and may be performed by dry etching using another gas or wet etching.

After the etching, the taper angle of the end surface of the organic compound layer 112R is preferably greater than or equal to 450 and less than 90°.

The insulating layer 104 is exposed when the organic compound film 112fR is etched. Thus, a depressed portion is sometimes formed in the insulating layer 104 in a region overlapping with a slit 118. Note that in the case where the depressed portion is not desired to be formed, a film highly resistant to etching treatment of the organic compound film 112fR is preferably used for the insulating layer 104. For example, an insulating film containing an inorganic material is preferably used as the insulating layer 104.

[Deposition to Etching of Green Organic Compound Film 112fG]

As illustrated in FIG. 15B, the organic compound layer 112G is formed using a mask layer 145G and a mask layer 147G with reference to the deposition to etching of the organic compound film 112fR. The taper angle of the end surface of the organic compound layer 112G is preferably greater than or equal to 450 and less than 90°. The organic compound layer 112G is an organic compound layer of the light-emitting device that emits green light.

[from Deposition to Etching of Blue Organic Compound Film 112fB]

As illustrated in FIG. 15B, the organic compound layer 112B is formed using a mask layer 145B and a mask layer 147B with reference to the deposition to etching of the organic compound film 112fR. The taper angle of the end surface of the organic compound layer 112B is preferably greater than or equal to 45° and less than 90°. The organic compound layer 112B is an organic compound layer of the light-emitting device that emits green light.

The term “organic compound layer 112” is used in the description of matters common to the organic compound layer 112R, the organic compound layer 112G, and the organic compound layer 112B. A functional layer having at least high heat resistance, e.g., an electron-transport layer, is preferably positioned on the outermost surface of the organic compound layer 112.

An organic compound film is not provided over the second wiring layer 151b, and the second wiring layer 151b is exposed.

The slit 118 is formed between the organic compound layers 112. That is, the width of the slit 118 which is indicated by the arrow in FIG. 15B and is between the organic compound layers 112 obtained through a processing step using a photolithography method can be less than or equal to 8 μm, less than or equal to 3 μm, less than or equal to 2 μm, or less than or equal to 1 μm. The width of the slit 118 corresponds to the distance between the subpixels. The distance between the subpixels is shortened in this manner, whereby a display apparatus with high resolution and a high aperture ratio can be provided.

The adjacent organic compound layers 112 are apart from each other as shown by the slit 118, which makes it possible to divide a leakage current path and accordingly inhibit leakage current (also referred to as side leakage or side leakage current). In this manner, an increased luminance, an increased contrast, improved display quality, enhanced power efficiency, reduced power consumption, or the like can be achieved in the light-emitting device.

The adjacent organic compound layers 112 preferably have the end surfaces facing to each other with the slit 118 therebetween. Note that the organic compound layer formed using a metal mask cannot have the end surfaces facing to each other. Thus, the organic compound layers whose end surfaces face to each other is different from the organic compound layer formed using a metal mask.

The insulating layer 104 is exposed when the organic compound film is etched. Thus, a depressed portion is sometimes formed in the insulating layer 104 in a region overlapping with the slit 118. Note that in the case where the depressed portion is not desired to be formed, a film highly resistant to etching of the organic compound film is preferably used for the insulating layer 104. For example, an insulating film containing an inorganic material is preferably used as the insulating layer 104.

### [Removal of Mask Layer]

As illustrated in FIG. 15C, the mask layer 147 is removed, and the top surface of the mask layer 145 is exposed.

[Formation of Insulating Film 125f]

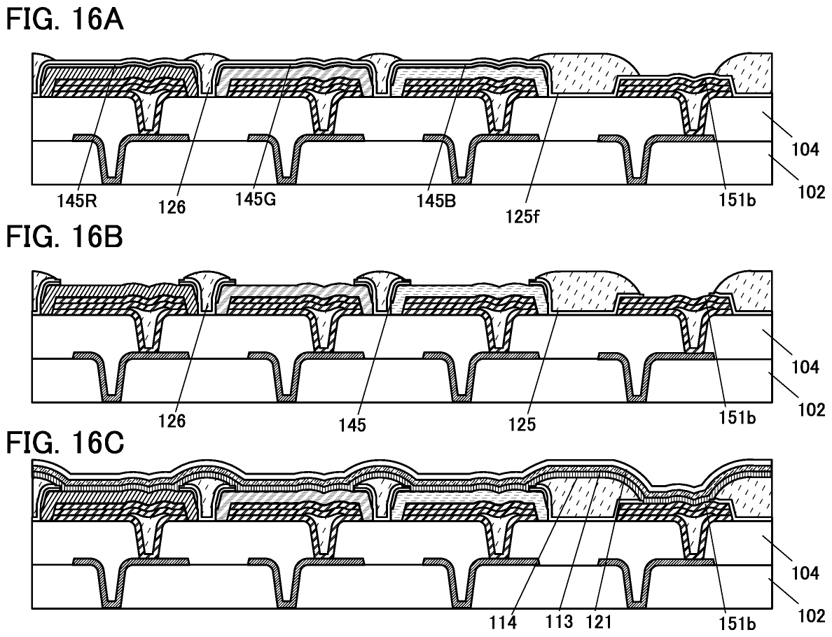

As illustrated in FIG. 16A, an insulating film 125f is deposited to cover the mask layer 145 and the second wiring layer 151b.

The insulating film 125f functions as a barrier layer that prevents diffusion of impurities such as water into the organic compound layer 112. The insulating film 125f is preferably formed by an ALD method with excellent step coverage so as to suitably cover the side surface of the organic compound layer 112.

The same film as the mask layer 145 and the mask layer 147 is preferably used as the insulating film 125f, in which case simultaneous removal is easily performed in etching treatment in a later step. For example, one or two or more inorganic insulating materials selected from aluminum oxide, hafnium oxide, silicon oxide, and the like, which is formed by an ALD method, is preferably used for the insulating film 125f, the mask layer 145, and the mask layer 147.

Note that the materials usable for the insulating film 125f are not limited thereto. For example, any of the materials usable for the mask layer 145 can be used as appropriate.

### [Formation of Insulating Layer 126]

As illustrated in FIG. 16A, the insulating layer 126 is formed in a region overlapping with the slit 118, for example. The insulating layer 126 can be formed by a method similar to that for the resin layer 163. For example, a photosensitive resin is formed, and then light exposure and development are performed, whereby the insulating layer 126 can be formed. The insulating layer 126 may be formed in the following manner: a resin is formed on the entire surface, and then is partly etched by ashing or the like.

Here, a structure is illustrated in which the insulating layer 126 has a larger width than the slit 118. Note that the insulating layer 126 is provided such that part of the top surface of the second wiring layer 151b is exposed.

### [Etching of Insulating Film 125f and Mask Layer 145]

As illustrated in FIG. 16B, portions of the insulating film 125f and the mask layer 145 that are not covered with the insulating layer 126 are removed by etching, so that part of the top surface of the organic compound layer 112 is exposed. Thus, the insulating layer 125 and the mask layer 145 remain in a region overlapping with the insulating layer 126. It is preferable that the center portion of the insulating layer 126 be positioned above the end portion of the insulating layer 126, and the center portion include a region rising above the end portion. The top surface of the insulating layer 126 is preferably positioned above the top surface of the organic compound layer 112. Furthermore, the end portion of the insulating layer 126 preferably has a tapered shape.

The insulating film 125f and the mask layer 145 are preferably etched in the same step. It is particularly preferable that the etching of the mask layer 145 be performed by wet etching that gives less etching damage to the organic compound layer 112. For example, wet etching using a tetramethyl ammonium hydroxide (TMAH) aqueous solution, diluted hydrofluoric acid, oxalic acid, phosphoric acid, acetic acid, nitric acid, or a mixed solution thereof is preferably used.

Alternatively, at least one of the sacrificial film 125f and the mask layer 145 are preferably removed by being dissolved in a solvent such as water or alcohol. For the alcohol in which the insulating film 125f and the mask layer 145 can be dissolved, any of various alcohols such as ethyl alcohol, methyl alcohol, isopropyl alcohol (IPA), and glycerin can be used.

After the insulating film 125f and the mask layer 145 are partly removed, drying treatment is preferably performed to remove water contained in the organic compound layers 112, or the like and water adsorbed on the surfaces thereof. For example, heat treatment is preferably performed in an inert gas atmosphere or a reduced-pressure atmosphere. The heat treatment can be performed at a substrate temperature higher than or equal to 50° C. and lower than or equal to 200° C., preferably higher than or equal to 60° C. and lower than or equal to 150° C., and further preferably higher than or equal to 70° C. and lower than or equal to 120° C. Employing a reduced-pressure atmosphere is preferable, in which case, drying at a lower temperature is possible.

Part of the top surface of the second wiring layer 151b is exposed by the removal of part of the insulating film 125f.

### [Formation of Common Layer 114]

As illustrated in FIG. 16C, the common layer 114 is deposited to cover the organic compound layer 112, the insulating layer 125, the mask layer 145, the insulating layer 126, and the like.

For the common layer 114, any of the above-described materials usable for the electron-injection layer can be used; for example, an alkali metal, an alkaline earth metal, or a compound thereof can be used. Examples of the above materials include a composite material of an organic compound and an alkali metal or an alkaline earth metal. Specifically, lithium fluoride (LiF), a composite material containing NBPhen and Ag, or the like is preferably used.

The common layer 114 can be deposited in a manner similar to that for the organic compound film 112fR or the like. To obtain the above composite material, deposition is preferably performed by co-evaporation.

### [Formation of Common Electrode 113]

As illustrated in FIG. 16C, the common electrode 113 is formed to cover the common layer 114.

The common electrode 113 can be formed by a deposition method such as an evaporation method or a sputtering method. Alternatively, a film formed by an evaporation method and a film formed by a sputtering method may be stacked.

The common electrode 113 is preferably formed so as to cover a region where the common layer 114 is deposited.

The common layer 114 may be positioned between the second wiring layer 151b and the common electrode 113. In this case, for the common layer 114, a material with as low electric resistance as possible is preferably used. Alternatively, it is preferable to form the common layer 114 as thin as possible, in which case the electric resistance of the common layer 114 in the thickness direction can be reduced. For example, an electron-injection or hole-injection material with a thickness greater than or equal to 1 nm and less than or equal to 5 nm, preferably greater than or equal to 1 nm and less than or equal to 3 nm, is used for the common layer 114, whereby electric resistance between the second wiring layer 151b and the common electrode 113 can be made small enough to be negligible.

The common layer 114 is not necessarily positioned between the second wiring layer 151b and the common electrode 113.

### [Formation of Protective Layer]

As illustrated in FIG. 16C, the protective layer 121 is formed over the common electrode 113. An inorganic insulating film used as the protective layer 121 is preferably deposited by a sputtering method, a PECVD method, or an ALD method. In particular, an ALD method is preferable because it provides excellent step coverage and is less likely to cause a defect such as a pinhole. In addition, an organic insulating film is preferably formed by an inkjet method, in which case a uniform film can be formed in a desired area.

### [Formation of Counter Substrate]

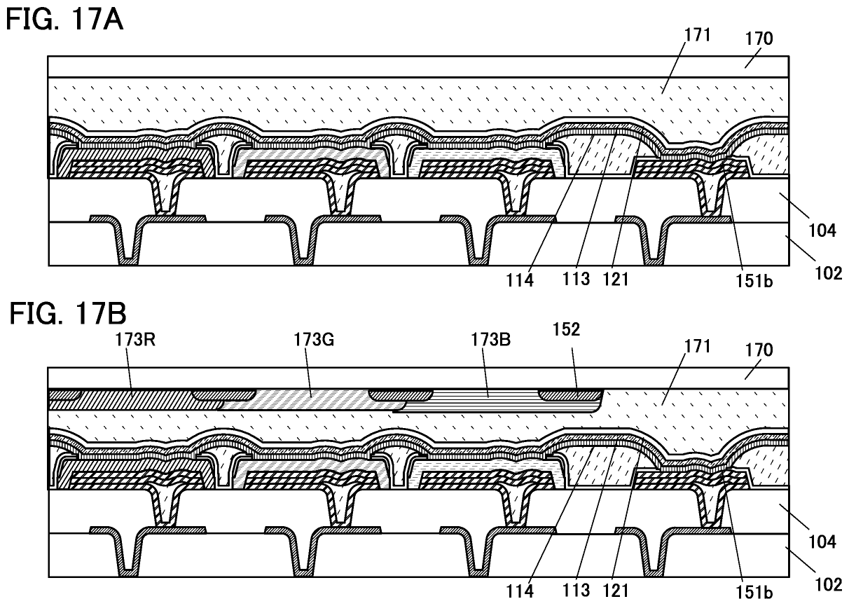

As illustrated in FIG. 17A, the substrate 170 is bonded with the adhesive layer 171. The bonded substrate 170 is referred to as a counter substrate in some cases. In the case where the display apparatus has a hollow sealing structure, the substrate 170 is preferably bonded with a sealant or the like. Although a space is generated when the substrate is bonded with the sealant, the space is preferably filled with an inert gas (a gas containing nitrogen or argon).

For the adhesive layer 171, an organic material such as a reactive curable adhesive, a photocurable adhesive, a thermosetting adhesive, or/and an anaerobic adhesive can be used, for example.

Specifically, an adhesive containing an epoxy resin, an acrylic resin, a silicone resin, a phenol resin, a polyimide resin, an imide resin, a PVC (polyvinyl chloride) resin, a PVB (polyvinyl butyral) resin, an EVA (ethylene vinyl acetate) resin, or the like can be used for the adhesive layer 171 or the like.

As illustrated in FIG. 17B, the substrate 170 is provided with a light-blocking layer 152, a coloring layer 173R, a coloring layer 173G, and a coloring layer 173B. The light-blocking layer 152 is provided in a region overlapping with the insulating layer 126. The substrate 170 is preferably bonded such that the coloring layer 173R, the coloring layer 173G, and the coloring layer 173B overlap with the lower electrodes 111R, 111G, and 111B, respectively.

Each of the coloring layer 173R, the coloring layer 173G, and the coloring layer 173B can be formed in a desired position by an inkjet method or through etching treatment using a photolithography method, for example. Specifically, the coloring layer 173 (the coloring layer 173R, the coloring layer 173G, or the coloring layer 173B) can be formed in the corresponding pixel.

Light emitted toward the common electrode 113 side is colored resulting from absorption of light in a predetermined wavelength range by the coloring layer 173R, the coloring layer 173G, or the coloring layer 173B (not illustrated) and the colored light exits through the substrate 170, enabling full color display.

In the above manner, the display apparatus can be manufactured.

### Manufacturing Method Example 2

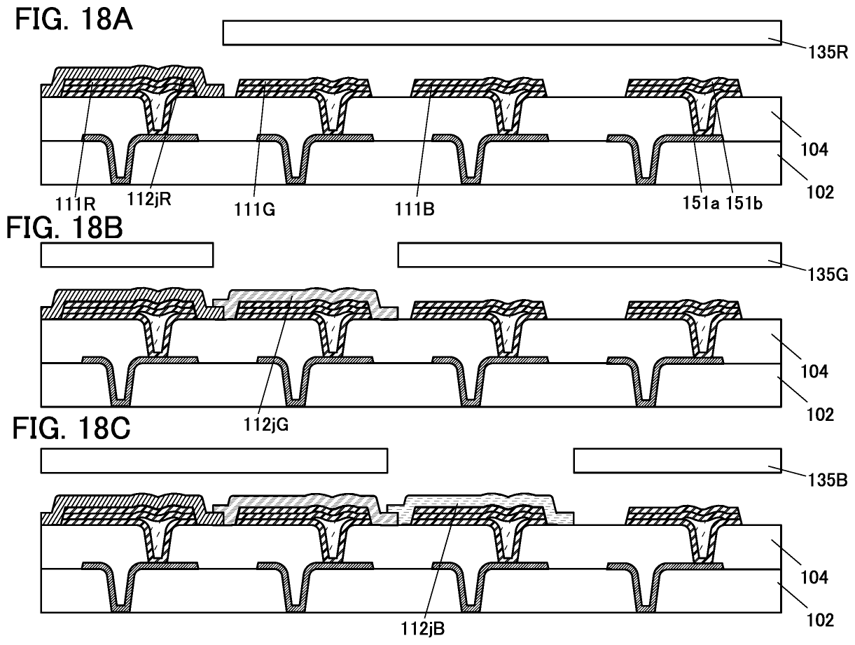

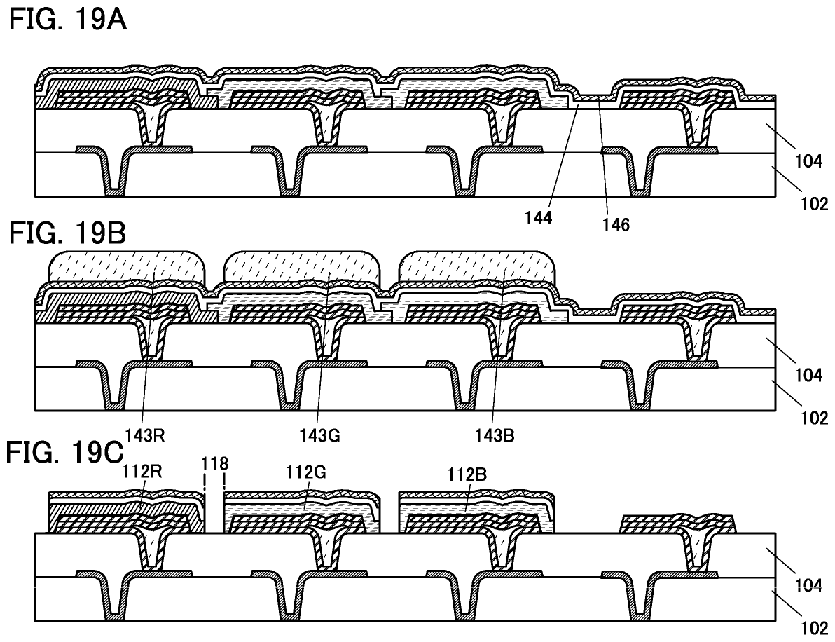

A manufacturing method using a metal mask is described with reference to FIG. 18, FIG. 19, and the like. In the drawings, a region of the pixel 150 is illustrated on the left side, and a region of the auxiliary wiring 151 is illustrated on the right side.

As in Manufacturing method example 1 described above, components up to the lower electrode 111 and the second wiring layer 151b are formed. As illustrated in FIG. 18A, an organic compound film 112jR is formed using a metal mask 135R. The organic compound film 112jR can be formed only in a region to be the red-light-emitting device with the use of the metal mask 135R.

As illustrated in FIG. 18B, an organic compound film 112jG is formed using a metal mask 135G. The organic compound film 112jG can be formed only in a region to be the green light-emitting device with the use of the metal mask 135G; however, the organic compound film 112jG includes a region overlapping with part of the organic compound film 112jR. That is, in a boundary between the light-emitting devices, the organic compound film includes a region overlapping with part of the organic compound film deposited first.

As illustrated in FIG. 18C, an organic compound film 112jB is formed using a metal mask 135B. The organic compound film 112jB can be formed only in a region to be the blue-light-emitting device with the use of the metal mask 135B; however, the organic compound film 112jB includes a region overlapping with part of the organic compound film 112jG. Although not illustrated, the organic compound film 112jB also includes a region overlapping with part of the organic compound film 112jR. That is, in the boundary between the light-emitting devices, the organic compound film includes a region overlapping with part of the organic compound film deposited first.

As illustrated in FIG. 19A, the mask film 144 and the mask film 146 are formed. The mask film 144 and the mask film 146 can be formed in a manner similar to that in Manufacturing method example 1.

As illustrated in FIG. 19B, the resist masks 143R, 143G, and 143B are formed. The resist masks 143R, 143G, and 143B can be formed in a manner similar to that in Manufacturing method example 1.

As illustrated in FIG. 19C, the organic compound films 112jR, 112jG, and 112jB are etched using the resist masks 143R, 143G, and 143B, respectively. The organic compound films 112jR, 112jG, and 112jB can be formed under the etching conditions and the like similar to those in Manufacturing method example 1. Thus, as in Manufacturing method example 1, the organic compound layers 112R, 112G, and 112B are formed with the slits 118 therebetween.

After that, as in Manufacturing method example 1, the insulating layer 126, the common layer 114, the common electrode 113, and the protective layer 121 are formed. Lastly, the substrate 170 and the like are bonded to each other, whereby the display apparatus can be manufactured.

At least part of this embodiment can be implemented in combination with the other embodiments described in this specification as appropriate.

### Embodiment 9

In this embodiment, a display apparatus of one embodiment of the present invention will be described with reference to drawings.

### [Specific Example of Display Apparatus]

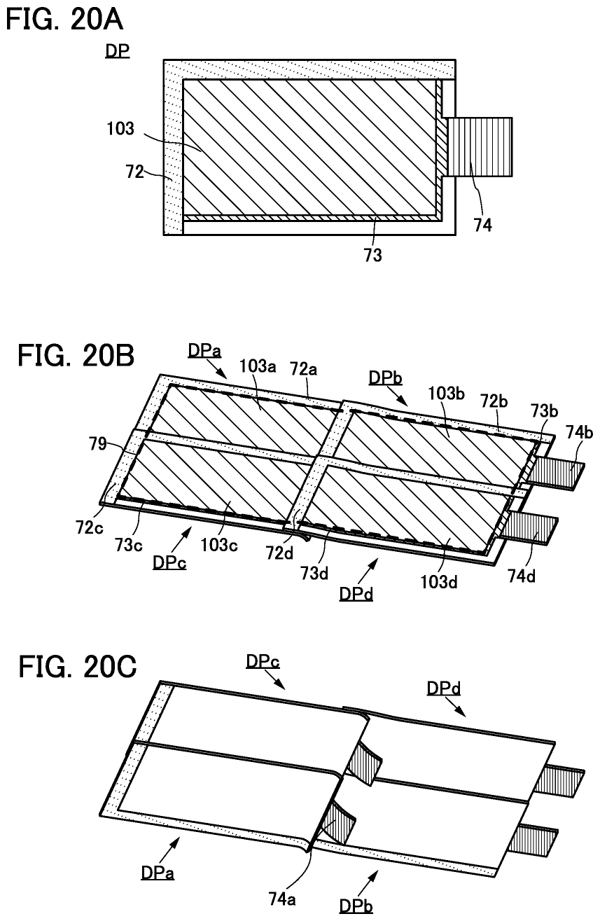

A large display apparatus including the display apparatus described in the above embodiment and a plurality of display modules DP including FPC 74 will be described with reference to FIG. 20.

FIG. 20A is a top view of the display module DP. The display module DP includes a region 73 blocking visible light and a region 72 which transmits visible light and is adjacent to the pixel portion 103.

FIG. 20B and FIG. 20C are perspective views of a display apparatus including four display modules DP. When a plurality of display modules DP are arranged in one or more directions (e.g., in one column or in a matrix), a large display apparatus with a large display region can be manufactured.

In the case where a large display apparatus is manufactured using a plurality of display modules DP, each of the display modules DP is not required to be large. Thus, an apparatus for manufacturing the display module DP does not need to be increased in size, whereby space-saving can be achieved. Furthermore, since an apparatus for manufacturing small- and medium-sized display panels can be used and a novel manufacturing apparatus does not need to be utilized for larger display apparatus, manufacturing cost can be reduced. In addition, a decrease in yield caused by an increase in the size of a display module DP can be suppressed.

The periphery of the pixel portion 103 is positioned in a non-display region where wirings and the like are routed. The non-display region corresponds to the region 73 blocking visible light. When the plurality of display modules DP overlap with each other, one image is perceived to be separated from each other by a non-display region or the like in some cases.

Thus, in one embodiment of the present invention, the region 72 transmitting visible light is provided in the display module DP, and in two display modules overlapping with each other, the pixel portion 103 of the display module DP placed on the lower side and the region 72 transmitting visible light of the display module DP placed on the upper side overlap with each other.

In this manner, with the region 72 transmitting visible light, the display module DP does not acquire active reduction in non-display regions. However, a non-display region is reduced in two display modules DP overlapping with each other, which is preferable. As a result, a large-sized display apparatus in which a seam between the display modules DP is hardly seen by a user can be obtained.

In the display module DP positioned on the upper side, the region 72 transmitting visible light may be provided in at least part of the non-display region. The region 72 transmitting visible light can overlap with the pixel portion 103 of the display module DP positioned on the lower side.

Furthermore, at least part of a non-display region of the display module DP on the lower side overlaps with the pixel portion 103 or the region 73 blocking visible light of the display module DP positioned on the upper side.

A large non-display region of the display module DP preferably leads to an increase in the distance between an end portion of the display module DP and an element in the display module DP, in which case the deterioration of the element due to impurities entering from the outside of the display module DP can be suppressed.

In the case where a plurality of display modules DP are provided in the display apparatus as described above, the pixel portion 103 is continuous between the adjacent display modules DP; thus, display region with a large area can be provided.

The pixel portion 103 includes a plurality of pixels.

In the region 72 transmitting visible light, a pair of substrates that constitutes the display module DP, a resin material for sealing a display element sandwiched between the pair of substrates, and the like may be provided. At this time, for members provided in the region 72 transmitting visible light, materials having a transmitting property with respect to visible light are used.

In the region 73 blocking visible light, for example, a wiring electrically connected to the pixel included in the pixel portion 103 may be provided. Moreover, one or both of a scan line driver circuit and a signal line driver circuit may be provided in the region 73 blocking visible light. Furthermore, a terminal connected to the FPC 74, a wiring connected to the terminal, or the like may be provided in the region 73 blocking visible light.

FIG. 20B and FIG. 20C each illustrate an example in which the display modules DP illustrated in FIG. 20A are arranged in a 2×2 matrix (two display modules DP are arranged in the longitudinal direction and the lateral direction). FIG. 20B is a perspective view of the display surface side of the display module DP, and FIG. 20C is a perspective view of the side opposite to the display surface side of the display module DP.

Four display modules DP (display modules DPa, DPb, DPc, and DPd) are arranged so as to have regions overlapping with each other. Specifically, the display modules DPa, DPb, DPc, and DPd are arranged such that the region 72 transmitting visible light that is included in one display module DP has a region overlapping with and located over the pixel portion 103 (on the display surface side) of another display module DP. In addition, the display modules DPa, DPb, DPc, and DPd are arranged such that the region 73 blocking visible light of one display module DP does not overlap with the pixel portion 103 of another display module DP. In a portion where four display modules DP overlap with each other, the display module DPb overlaps with the display module DPa, the display module DPc overlaps with the display module DPb, and the display module DPd overlaps with the display module DPc.

The short side of the display module DPa and the short side of the display module DPb overlap with each other, and part of a pixel portion 103a and part of a region 72b transmitting visible light overlap with each other. Furthermore, the long side of the display module DPa and the long side of the display module DPc overlap with each other, and part of the pixel portion 103a and part of a region 72c transmitting visible light overlap with each other.

Part of a pixel portion 103b overlaps with part of the region 72c transmitting visible light and part of a region 72d transmitting visible light. In addition, part of a pixel portion 103c overlaps with part of the region 72d transmitting visible light.

Thus, a region where the pixel portion 103a to the pixel portion 103d are placed almost seamlessly can be a display region 79.

Here, it is preferable that the display module DP have flexibility. For example, a pair of substrates included in the display module DP preferably have flexibility.

Thus, as illustrated in FIG. 20B and FIG. 20C, a region near an FPC 74a of the display module DPa can be bent so that part of the display module DPa and part of the FPC 74a can be placed under the pixel portion 103b of the display module DPb adjacent to the FPC 74a. As a result, the FPC 74a can be placed without physical interference with the rear surface of the display module DPb. Furthermore, when the display module DPa and the display module DPb overlap with each other and are fixed, it is not necessary to consider the thickness of the FPC 74a; thus, the level difference between the top surface of the region 72b transmitting visible light and the top surface of the display module DPa can be reduced. This can make an end portion of the display module DPb placed over the pixel portion 103a less noticeable.

Moreover, when each display module DP is made flexible, the display module DPb can be curved gently so that the top surface of the pixel portion 103b of the display module DPb is level with the top surface of the pixel portion 103a of the display module DPa. Thus, the display regions can be level with each other except in the vicinity of a region where the display module DPa and the display module DPb overlap with each other, and the display quality of an image displayed on the display region 79 can be improved.

Although the relation between the display module DPa and the display module DPb is taken as an example in the above description, the same can apply to the relation between any other two adjacent display modules DP.

Note that to reduce a step between two adjacent display modules DP, the thicknesses of the display modules DP are preferably small. For example, the thickness of the display module DP is preferably less than or equal to 1 mm, further preferably less than or equal to 300 μm, and still further preferably less than or equal to 100 μm.

The display module DP preferably incorporates both a scan line driver circuit and a signal line driver circuit. In the case where a driver circuit is provided separately from the display panel, a printed circuit board including a driver circuit and a large number of wirings, terminals, and the like are provided on the back side (the side opposite to the display surface side) of the display panel. Thus, the number of components of the whole display apparatus becomes enormous, which leads to an increase in weight of the display apparatus in some cases. When the display module DP incorporates both a scan line driver circuit and a signal line driver circuit, the number of components of the display apparatus can be reduced and the weight of the display apparatus can be reduced. This leads to higher portability of the display apparatus.

Here, the scan line driver circuit and the signal line driver circuit are required to operate at a high driving frequency in accordance with the frame frequency of an image to be displayed. In particular, the signal line driver circuit is required to operate at a higher driving frequency than the scan line driver circuit. Thus, some transistors used for the signal line driver circuit require large current supply capability in some cases. Meanwhile, some transistors provided in the pixel portion require adequate withstand voltage for driving a display element in some cases.

In view of the above, the transistor of the driver circuit and the transistor of the pixel portion are preferably formed to have different structures. For example, one or a plurality of transistors provided in the pixel portion are transistors with high withstand voltage, and one or a plurality of transistors provided in the driver circuit are transistors with high driving frequency.

Specifically, one or a plurality of transistors used for the signal line driver circuit are transistors each including a thinner gate insulating layer than the transistor used for the pixel portion. By forming two kinds of transistors separately as described above, the signal line driver circuit can be formed over the substrate over which the pixel portion is provided.

In each transistor used for the scan line driver circuit, the signal line driver circuit, and the pixel portion, a metal oxide is preferably used for a semiconductor in which a channel is formed.

In each transistor used for the scan line driver circuit, the signal line driver circuit, and the pixel portion, silicon is preferably used for a semiconductor in which a channel is formed.

For transistors used for the scan line driver circuit, the signal line driver circuit, and the pixel portion, a transistor in which a metal oxide is used in a semiconductor where a channel is formed and a transistor in which silicon is used in a semiconductor where a channel is formed are preferably used in combination.

At least part of this embodiment can be implemented in combination with the other embodiments described in this specification as appropriate.

### Embodiment 10

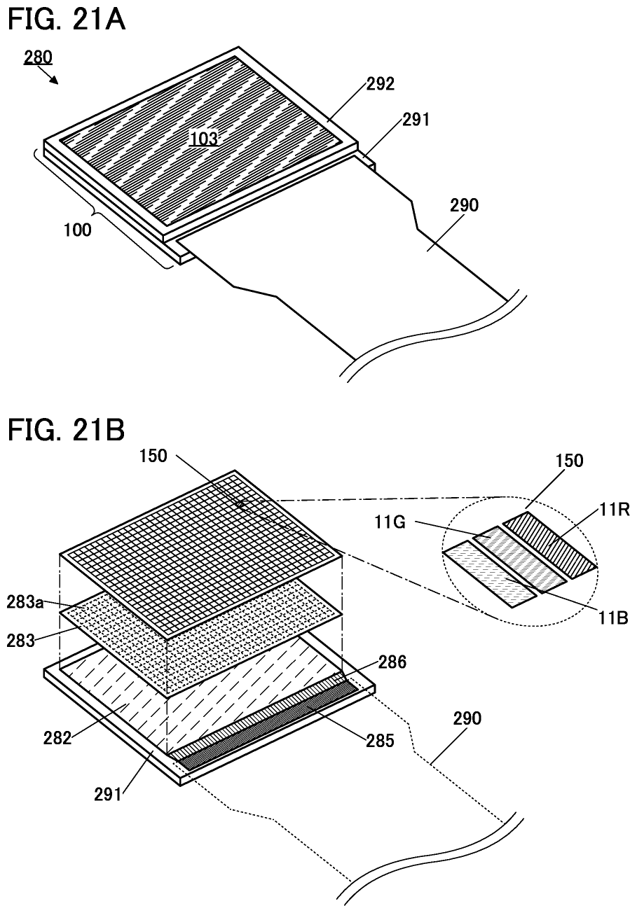

In this embodiment, a display apparatus of one embodiment of the present invention will be described with reference to FIG. 21.

The display apparatus in this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on a head, such as a VR device like a head mounted display and a glasses-type AR device.

### [Display Module]

FIG. 21A is a perspective view of a display module 280. The display module 280 includes the display apparatus 100 and an FPC 290.

The display module 280 includes a substrate 291 and a substrate 292. The display module 280 includes a display portion 103. The display portion 103 is a region of the display module 280 where an image is displayed, and is a region where light emitted from pixels provided in a pixel portion 103 described later can be seen.

FIG. 21B is a perspective view schematically illustrating a structure on the substrate 291 side. Over the substrate 291, a circuit portion 282, a pixel circuit portion 283 over the circuit portion 282, and the pixel portion 103 over the pixel circuit portion 283 are stacked. A terminal portion 285 (sometimes referred to as an FPC terminal portion) to be connected to the FPC 290 is provided in a portion over the substrate 291 that does not overlap with the pixel portion 103. The terminal portion 285 and the circuit portion 282 are electrically connected to each other through a wiring portion 286 formed of a plurality of wirings.

The pixel portion 103 includes a plurality of pixels 150 arranged periodically. An enlarged view of one pixel 150 is illustrated on the right side of FIG. 21B. The pixel 150 includes the light-emitting device 11R, the light-emitting device 11G, and the light-emitting device 11B that emit light of different colors. The plurality of light-emitting devices can be laid out in a stripe pattern as illustrated in FIG. 21B. Alternatively, a variety of arrangement methods of light-emitting devices, such as delta arrangement and PenTile arrangement, can be employed.

The pixel circuit portion 283 includes a plurality of pixel circuits 283a including transistors or the like arranged periodically.

One pixel circuit 283a is a circuit that controls light emission of light-emitting devices included in one pixel 150. One pixel circuit 283a may be provided with three circuits each of which controls light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to one of a source and a drain of the selection transistor. Thus, an active-matrix display apparatus is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the display portion 103; hence, the aperture ratio (effective display area ratio) of the display portion 103 can be significantly high. For example, an aperture ratio of the display portion 103 can be greater than or equal to 40% and less than 100%, preferably greater than or equal to 50% and less than or equal to 95%, and further preferably greater than or equal to 60% and less than or equal to 95%. Furthermore, the pixels 150 can be laid out extremely densely, and thus the resolution of the display portion 103 can be extremely high. For example, the pixels 150 are preferably laid out in the display portion 103 with a resolution greater than or equal to 2000 ppi, preferably greater than or equal to 3000 ppi, further preferably greater than or equal to 5000 ppi, and still further preferably greater than or equal to 6000 ppi, and less than or equal to 20000 ppi or less than or equal to 30000 ppi.

Such a display module 280 has extremely high resolution, and thus can be suitably used for a VR device such as a head-mounted display or a glasses-type AR device. For example, even with a structure in which the display portion of the display module 280 is seen through a lens, pixels of the extremely-high-resolution display portion 103 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wrist watch.

### Embodiment 11

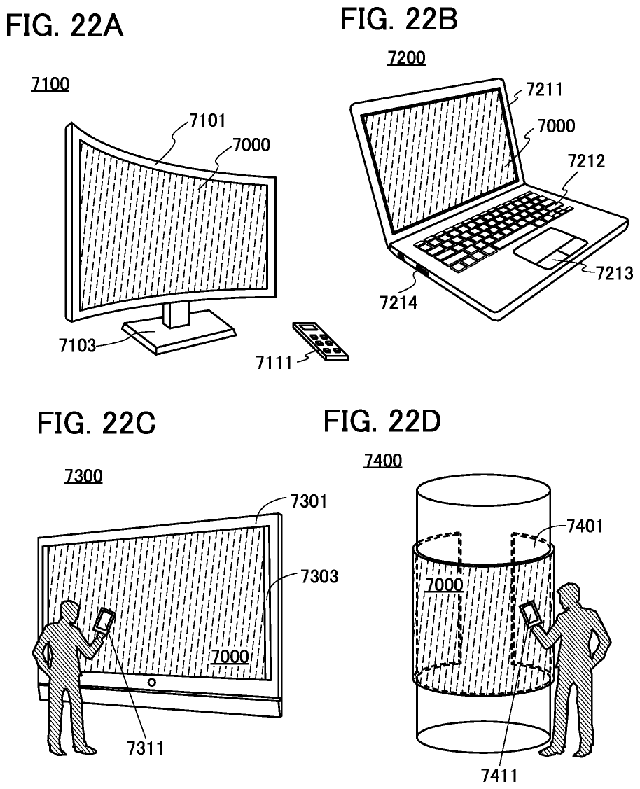

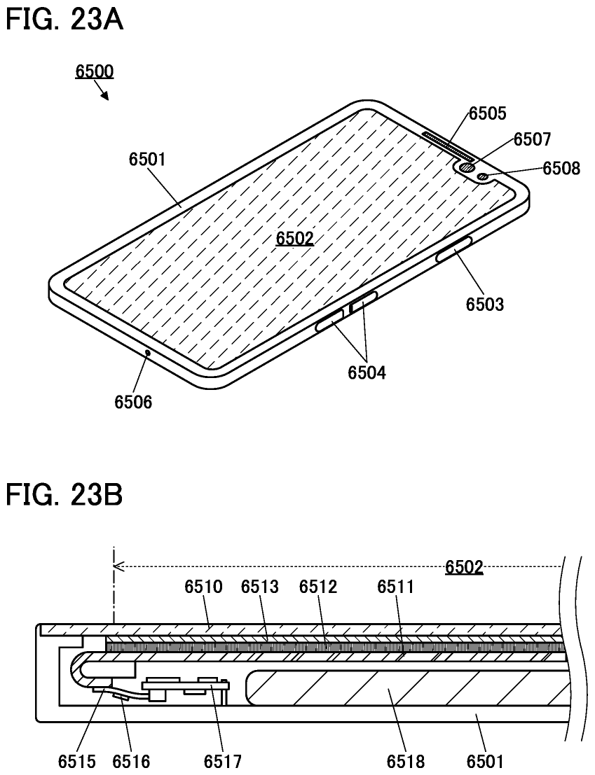

In this embodiment, electronic devices of one embodiment of the present invention will be described with reference to FIG. 22 and FIG. 23.

An electronic device of this embodiment is provided with the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of electronic devices include a digital camera, a digital video camera, a digital photo frame, a mobile phone, a portable game console, a portable information terminal, and an audio reproducing device in addition to electronic devices with a relatively large screen, such as a television device, a desktop or laptop personal computer, a monitor of a computer or the like, digital signage, and a large game machine like a pachinko machine.

In particular, a display apparatus of one embodiment of the present invention can have a high resolution, and thus can be suitably used for an electronic device having a relatively small display portion. Examples of such an electronic device include a watch-type or a bracelet-type information terminal device (wearable device), and a wearable device worn on a head, such as a device for VR such as a head mounted display, a glasses-type device for AR, and a device for MR.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. Furthermore, the pixel density (resolution) of the display apparatus of one embodiment of the present invention is preferably higher than or equal to 100 ppi, preferably higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, and yet further preferably higher than or equal to 7000 ppi. With the use of such a display apparatus with one or both of high definition and high resolution, the electronic device can have higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

FIG. 22A illustrates an example of a television device. In a television device 7100, a pixel portion 7000 is incorporated in a housing 7101. Here, the housing 7101 is supported by a stand 7103.

The pixel portion 103 of one embodiment of the present invention can be used for the pixel portion 7000.

Operation of the television device 7100 illustrated in FIG. 22A can be performed with an operation switch provided in the housing 7101 and a separate remote control 7111. Alternatively, the pixel portion 7000 may include a touch sensor, and the television device 7100 may be operated by touch on the pixel portion 7000 with a finger or the like. The remote control 7111 may be provided with a display portion for displaying information output from the remote control 7111. With operation keys or a touch panel provided in the remote control 7111, channels and volume can be operated and videos displayed on the pixel portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 22B illustrates an example of a laptop personal computer. The laptop personal computer 7200 includes a housing 7211, a keyboard 7212, a pointing device 7213, an external connection port 7214, and the like. In the housing 7211, the pixel portion 7000 is incorporated.

The pixel portion 103 of one embodiment of the present invention can be used for the pixel portion 7000.

FIG. 22C and FIG. 22D illustrate examples of digital signage.

Digital signage 7300 illustrated in FIG. 22C includes a housing 7301, the pixel portion 7000, a speaker 7303, and the like. The digital signage 7300 can also include an LED lamp, an operation key (including a power switch or an operation switch), a connection terminal, a variety of sensors, a microphone, and the like.

FIG. 22D is digital signage 7400 attached to a cylindrical pillar 7401. The digital signage 7400 includes the pixel portion 7000 provided along a curved surface of the pillar 7401.

The pixel portion 103 of one embodiment of the present invention can be used for the pixel portion 7000 in FIG. 22C and FIG. 22D.

A larger area of the pixel portion 7000 can increase the amount of data that can be provided at a time. The larger pixel portion 7000 attracts more attention, so that the effectiveness of the advertisement can be increased, for example.

The use of a touch panel in the pixel portion 7000 is preferable because in addition to display of a still image or a moving image on the pixel portion 7000, intuitive operation by a user is possible. Moreover, for an application for providing information such as route information or traffic information, usability can be enhanced by intuitive operation.

As illustrated in FIG. 22C and FIG. 22D, it is preferable that the digital signage 7300 or the digital signage 7400 can work with an information terminal 7311 or an information terminal 7411 such as a smartphone a user has through wireless communication. For example, information of an advertisement displayed on the pixel portion 7000 can be displayed on a screen of the information terminal 7311 or the information terminal 7411. By operation of the information terminal 7311 or the information terminal 7411, display on the pixel portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

An electronic device 6500 illustrated in FIG. 23A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The pixel portion 103 of one embodiment of the present invention can be used in the display portion 6502.

FIG. 23B is a cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of the pixel portion, whereby an electronic device with a narrow bezel can be achieved.

This embodiment can be combined with the other embodiments as appropriate. In the case where a plurality of structure examples are described in one embodiment in this specification, the structure examples can be combined as appropriate.

### REFERENCE NUMERALS

103: pixel portion, 151: auxiliary wiring, 151a: first wiring layer, 151b: second wiring layer, 14: insulating layer, 15: contact hole, 11R: light-emitting device, 11G: light-emitting device, 111B: light-emitting device, 111R: lower electrode, 111G: lower electrode, 111B: lower electrode, 112R: organic compound layer, 112G: organic compound layer, 112B: organic compound layer, 113: common electrode, 153a: third wiring layer, 153b: fourth wiring layer, 154: bridge wiring

1. A display apparatus comprising:
a first light-emitting device comprising:
a first lower electrode, and
a first organic compound layer over the first lower electrode;
a second light-emitting device comprising:
a second lower electrode, and
a second organic compound layer over the second lower electrode;
a common electrode included in the first light-emitting device and the second light-emitting device; and
an auxiliary wiring electrically connected to the common electrode,
wherein the auxiliary wiring comprises a first wiring layer and a second wiring layer,
wherein the second wiring layer is electrically connected to the first wiring layer through a contact hole in an insulating layer, and
wherein the second wiring layer has a lattice shape in a top view.

2. A display apparatus comprising:
a first light-emitting device comprising:
a first lower electrode, and
a first organic compound layer over the first lower electrode;
a second light-emitting device comprising:
a second lower electrode, and
a second organic compound layer over the second lower electrode;
a common electrode included in the first light-emitting device and the second light-emitting device; and
an auxiliary wiring electrically connected to the common electrode,
wherein the auxiliary wiring comprises a first wiring layer and a second wiring layer,
wherein the second wiring layer is electrically connected to the first wiring layer through a contact hole in an insulating layer,
wherein the first wiring layer has a lattice shape in a top view, and
wherein the first lower electrode, the second lower electrode, and the second wiring layer each comprise a region over the insulating layer.

3. A display apparatus comprising:
a first light-emitting device comprising:
a first lower electrode, and
a first organic compound layer over the first lower electrode;
a second light-emitting device comprising:
a second lower electrode, and
a second organic compound layer over the second lower electrode;
a common electrode included in the first light-emitting device and the second light-emitting device; and
an auxiliary wiring electrically connected to the common electrode,
wherein the auxiliary wiring comprises a first wiring layer and a second wiring layer,
wherein the second wiring layer is electrically connected to the first wiring layer through a contact hole in an insulating layer,
wherein the first wiring layer and the second wiring layer each have a lattice shape in a top view,
wherein the first lower electrode, the second lower electrode, and the second wiring layer each comprise a region over the insulating layer, and
wherein a width of the second wiring layer is smaller than a width of the first wiring layer.

4. The display apparatus according to claim 1, wherein end portions of the first lower electrode and the second lower electrode each have a tapered shape.

5. The display apparatus according to claim 1, wherein a taper angle of an end face of the first organic compound layer is greater than or equal to 45° and less than 90°.

6. The display apparatus according to claim 1, wherein a taper angle of an end face of the second organic compound layer is greater than or equal to 450 and less than 90°.

7. The display apparatus according to claim 2, wherein end portions of the first lower electrode and the second lower electrode each have a tapered shape.

8. The display apparatus according to claim 2, wherein a taper angle of an end face of the first organic compound layer is greater than or equal to 45° and less than 90°.

9. The display apparatus according to claim 2, wherein a taper angle of an end face of the second organic compound layer is greater than or equal to 45° and less than 90°.

10. The display apparatus according to claim 3, wherein end portions of the first lower electrode and the second lower electrode each have a tapered shape.

11. The display apparatus according to claim 3, wherein a taper angle of an end face of the first organic compound layer is greater than or equal to 45° and less than 90°.

12. The display apparatus according to claim 3, wherein a taper angle of an end face of the second organic compound layer is greater than or equal to 45° and less than 90°.
